(19) United States
(12) Patent Application Publication
(10) Pub. No.: US 2004/0016456 A1
(43) Pub. Date: Jan. 29, 2004

(54) Photovoltaic device and method for producing the same

(75) Inventors: Mikio Murozono, Osaka (JP); Yoshimitsu Hiroshima, Osaka (JP); Ryoji Okazaki, Osaka (JP); Takeo Takayanagi, Nara-shi (JP); Satoshi Omae, Kyoto-shi (JP)

Correspondence Address: MCDERMOTT, WILL & EMERY, 600 13th Street, N.W., WASHINGTON, DC, 20005-3096, US

(73) Assignee: CLEAN VENTURE 21 CORPORATION

(21) Appl. No.: 10/621,439

(22) Filed: Jul. 18, 2003

(30) Foreign Application Priority Data
Jul. 25, 2002 (JP) JP2002-216649
Aug. 30, 2002 (JP) JP2002-254454
Oct. 18, 2002 (JP) JP2002-304225

(51) Int. Cl. H01L 25/00

(52) U.S. Cl. 136/250; 438/63

(57) ABSTRACT

A photovoltaic device comprising a plurality of spherical photovoltaic elements, a support and a first conductor layer and its production method are disclosed. Each of the photovoltaic elements comprises a spherical first semiconductor and a second semiconductor layer covering the surface thereof, the second semiconductor layer having an opening through which a part of the first semiconductor is exposed. An electrode is formed on each of the exposed part of the first semiconductor and the outer surface of the second semiconductor layer. The support has a plurality of recesses, each having a connection hole in its bottom, and comprises an electric insulator layer having the connection holes and a second conductor layer which is formed on the electric insulator layer except around the connection holes and which constitutes the inner surface of the recesses. The first conductor layer is disposed on the backside of the support. According to this production method, the photovoltaic element is disposed in each of the recesses of the support such that the opening of the second semiconductor layer and the exposed part of the first semiconductor are in contact with the electric insulator layer around the connection hole, and the contact parts are preferably bonded with an adhesive or melt-welded. Each electrode is electrically connected to the corresponding conductor layer, preferably with solder.

### BACKGROUND OF THE INVENTION

The present invention relates to a photovoltaic device comprising substantially spherical photovoltaic elements and a production method thereof.

A typical related art technique provides a crystal silicon solar cell comprising a photovoltaic element composed of a crystal silicon semiconductor wafer. This solar cell is produced by a complicated process including a step of producing a bulk single crystal and a step of producing a semiconductor wafer from the bulk single crystal, the latter step involving cutting, slicing, polishing, etc. Therefore, the production cost of this solar cell is high. Further, this production process is wasteful because crystal waste produced by cutting, slicing, policing, etc., amounts to about50% by volume or more of the original bulk single crystal.

In order to solve these problems, another related art technique provides an amorphous silicon solar cell comprising a semiconductor layer composed of an amorphous silicon (hereinafter referred to as a-Si) thin film. Since the photovoltaic layer of this solar cell is formed in the form of a thin film by the plasma CVD (chemical vapor deposition) method, this solar cell does not require the above-mentioned step involving cutting, slicing, policing, etc., and has an advantage that the deposited film can be used in its entirety as a photovoltaic active layer. However, the semiconductor of the a-Si solar cell has a large number of crystal defects resulting from the amorphous structure, and the crystal defects cause performance deterioration due to light irradiation, leading to a decrease in photoelectric conversion efficiency. To solve this problem, a technique of inactivation by hydrogenation treatment has been examined, but even with such treatment, the adverse effects of the crystal defects cannot be eliminated. Therefore, the a-Si solar cell has a disadvantage that the photoelectric conversion efficiency decreases by about 15 to 25 % when used for a few years, and its practicality is insufficient.

As another measure for making effective use of the silicon material, still another related art technique provides a photovoltaic device which employs a spherical photovoltaic element (hereinafter referred to as a spherical element) comprising a spherical p-type semiconductor coated with an n-type semiconductor layer. For example, Japanese Examined Patent Publication No. Hei 7-54855 discloses a solar array which includes silicon spherical elements each comprising a p-type semiconductor and an n-type semiconductor layer covering the surface of the p-type semiconductor. The silicon spherical elements are embedded in holes of a flat sheet of aluminum foil, and the n-type semiconductor layers are etched away from the back side of the aluminum foil sheet to expose the internal p-type semiconductors. The exposed p-type semiconductors are connected to another sheet of aluminum foil to form the solar array. This solar array utilizes small spherical elements having a diameter of around 1 mm to decrease the average thickness of the whole photovoltaic section, thereby enabling a reduction in the amount of high-purity silicon for cost reduction.

Further, U.S. Pat. No. 6,204,545 B1, for example, proposes a photovoltaic device comprising spherical elements connected in series. Each of the spherical elements comprises a crystal sphere having a photovoltaic part on its surface, with a pair of electrodes formed on the opposite edges of the crystal sphere. Also, Japanese Laid-Open Patent Publication No. 2001-339086, for example, proposes a solar cell comprising a plurality of spherical elements fixed inside a groove whose side walls constitute reflecting surfaces. Since these photovoltaic devices comprising spherical elements make no use or little use of reflected light, the output per spherical element is small. Thus, in order to improve the output per light-receiving surface of the device, these photovoltaic devices need to have a dense arrangement of a large number of small spherical elements. As a result, the process for connecting the spherical elements to the aluminum foil sheet becomes complicated, and moreover, the number of necessary spherical elements becomes extremely large, so that the cost of the photovoltaic device cannot be reduced sufficiently.

In order to solve the above-described problems associated with the photovoltaic devices comprising spherical elements, still another related art technique proposes a photovoltaic device comprising spherical elements, called micro concentrator-type or low concentrator-type, in which a single spherical element is disposed in each of a large number of recesses formed on a support. As disclosed in Japanese Laid-Open Patent Publications No. Hei 11-31837 and No. 2002-164554, for example, these photovoltaic devices allow the inner face of each recess to serve as a reflecting mirror to enhance the light-gathering ratio, with the aim of heightening the output per spherical element and reducing the amount of silicon consumption.

FIG. 33 illustrates an example of the photovoltaic devices comprising spherical elements, which is disclosed in Japanese Laid-Open Patent Publication No. 2002-50780. A support 103 is composed of a first conductor layer 100, an electric insulator layer 101 and a second conductor layer 102, and the trilaminar support 103 has a plurality of recesses 104. A spherical element 105 is disposed in each of the recesses 104. Part of a second conductivity-type semiconductor layer 106, which is the surface layer of the spherical element 105, is removed by etching such that an exposed part 108 is formed at part of a spherical first conductivity-type semiconductor 107. The exposed part 108 of the first conductivity-type semiconductor is in mechanical contact with the first conductor layer 100, while the second conductivity-type semiconductor layer 106 is in mechanical contact with the edge of an opening of the second conductor layer 102 or its vicinity. Through these mechanical contacts, the first conductivity-type semiconductors 107 are electrically connected to the first conductor layer 100, and the second conductivity-type semiconductor layers 106 are electrically connected to the second conductor layer 102.

In this proposal, the spherical elements accommodated in the respective recesses of the support are pressed from above, whereby the outer faces of the second conductivity-type semiconductor layers are fitted into the openings of the second conductor layer to bring the exposed parts of the first conductivity-type semiconductors in contact with the first conductor layer. Further, while the spherical elements are pressed in this manner, they are heated from above at approximately 150° C. for one hour and then subjected to a sintering treatment in an oxygen-free atmosphere at 200 to 300° C. for 30 minutes to one hour. These pressing and heating treatments are thought to be capable of electrically connecting the first and second conductor layers made of aluminum foil to the first and second conductivity-type semiconductors, respectively, and therefore of realizing a reduction in resistance of the connected parts without conductive material or the like. In fact, however, only the direct contacts of the conductor layers and the semiconductors or the additional application of the heating treatment in such temperature range causes the connected parts to have large contact resistance. Further, the contact resistance varies widely. Thus, this becomes a great hindrance to an improvement of the conversion efficiency of the photovoltaic device.

In order to obtain good electrical connection between the aluminum conductor layers and the silicon semiconductors which are in direct contact with one another, U.S. Pat. No. 4,806,495, for example, proposes a method of applying a heat treatment at 500 to 577° C. to form an alloy layer of aluminum and silicon at the connected parts. However, since it is difficult to select a resin material of the electric insulator layer which can withstand the heat treatment of such high temperatures, this heat treatment is not applicable to the production process of the photovoltaic device having the step of disposing the spherical element in the recess of the support having the insulator layer made of resin.

Further, it is conventionally preferred that the second conductivity-type semiconductor layer have a thickness of not greater than 0.5 μm, since the photoelectric conversion efficiency increases with decreasing thickness of the second conductivity-type semiconductor layer. However, if the thickness of the second conductivity-type semiconductor layer becomes, for example, 1.0 μm or less, the above method has the following problem. In forming the alloy layer of aluminum and silicon at the contact part between the second conductor layer and the second conductivity-type semiconductor layer, the aluminum opening edges of the second conductor layer may pierce the second conductivity-type semiconductor layer, causing a phenomenon of a short-circuit between the first conductivity-type semiconductor and the second conductivity-type semiconductor layer.

In order to prevent the short-circuit phenomenon without lowering the conversion efficiency, the alloy layer is formed on the second conductivity-type semiconductor layer having a thickness of not less than 1.0 μm according to the above method, and the thickness of the second conductivity-type semiconductor layer serving as the light-receiving surface is reduced by etching to, for example, approximately 0.5 μm (for more detail, see pages 1045-1048 of 22nd IEEE PVSC Proc. by J. D. Levine et al.). Since the above prior art method requires such complicated steps like this, it has a problem of being unable to achieve cost reduction

In order to solve this problem, it is necessary to dispose the spherical element, on which electrodes are formed in advance, in the recess of the support and thereafter electrically connect the electrodes to the conductor layers. The electrodes may be formed by various methods such as a method of depositing a metal film on a silicon wafer substrate by metal mask, a method of applying photo-etching after the metal film deposition and a method of thermally treating a screen-printed film of a conductive-material-containing paste. These methods, however, are not applicable to the formation of electrodes on the spherical element whose electrode-forming surfaces are curved or extremely small.

A prior art technique relating to the formation of electrodes on the silicon semiconductor spherical element is disclosed in U.S. No. 6,204,545 B1. As illustrated in FIG. 34, electrodes are formed on a spherical element in which a first conductivity-type semiconductor 201 (spherical silicon semiconductor) is covered, except a part thereof, with a second conductivity-type semiconductor layer 202. As illustrated in FIG. 34(a), the first conductivity-type semiconductor 201 and the second conductivity-type semiconductor layer 202 are masked with corrosion-resistant photosensitive resin films 203 except their respective electrode-forming-regions. Then, as illustrated in FIG. 34 (b), titanium and nickel are deposited in this order to form thin metallic films 204 and 205 having a thickness of approximately 0.1 to 1.0 μm. Thereafter, as illustrated in FIG. 34(c), the photosensitive resin films 203 are removed to form electrodes 206 and 207 on the first conductivity-type semiconductor 201 and the second conductivity-type semiconductor layer 202, respectively.

This technique makes it possible to form an electrode capable of good Ohmic contact without causing an internal short-circuit even when the second conductivity-type semiconductor layer is thin. However, this technique requires many complicated steps such as formation of the photosensitive resin films, deposition of the thin metallic films and removal of the photosensitive resin films, which becomes a major hindrance to a cost reduction.

Furthermore, the photovoltaic devices comprising spherical elements are faced with a very important problem of fixing each of the large number of spherical elements to the predetermined position of each of the recesses of the support. In order to solve this problem, as described above, it has been proposed to fit the bottom of the spherical element into the opening of the second conductor layer of the recess of the support and heat it in this state, but this proposal does not necessarily produce sufficient fixing effects. Thus, there are problems such as frequent occurrence of a short-circuit between the first conductivity-type semiconductor and the second conductivity-type semiconductor layer during the production process and a poor electrical connection between the semiconductor and the conductor layer. In addition, when a photovoltaic device is produced in such a state that the spherical elements are not fixed to the predetermined positions, a short-circuit and a poor electrical connection are liable to occur due to deviation of the spherical elements from the predetermined positions while handling and in use. When the inner faces of the recesses of the support also serve as reflecting mirrors, deviation of the spherical elements from the predetermined positions lowers the light gathering efficiency of reflected light, causing a problem of decreased output.

### BRIEF SUMMARY OF THE INVENTION

The present invention is aimed at solving the above-discussed problems associated with the photovoltaic device which has such a structure that a single spherical element is embedded in each of a plurality of recesses formed on a support.

An object of the present invention is to provide a high-performance and high-quality photovoltaic device by disposing the spherical element at a predetermined position of each of the recesses in a reliable manner and electrically connecting semiconductors of the spherical element and conductor layers with low resistance.

Another object of the present invention is to provide a method of effectively producing such a photovoltaic device.

A first method for producing a photovoltaic device in accordance with the present invention comprises the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) disposing the photovoltaic element in the recess of the support such that the opening of the second conductivity-type semiconductor layer and a peripheral part of the exposed part of the first conductivity-type semiconductor are in contact with the electric insulator layer around the connection hole; (6) electrically connecting the second electrode to the second conductor layer; and (7) electrically connecting the first electrode to a first conductor layer disposed on the backside of the support through the connection hole.

It is preferable that the first conductivity-type semiconductor and the second conductivity-type semiconductor layer be composed mainly of silicon.

In the method of producing a photovoltaic device in accordance with the present invention, the step (2) preferably comprises applying a conductive ink onto the exposed part of the first conductivity-type semiconductor and subjecting it to a heat treatment. The step (3) preferably comprises applying a conductive ink onto a part of the surface of the second conductivity-type semiconductor layer and subjecting it to a heat treatment.

It is preferable that the conductive ink comprise glass frit and at least one selected from the group consisting of silver, aluminum, tin, nickel, copper, phosphorus and phosphorus compounds, and that the temperature range of the heat treatment be 500 to 750° C.

It is preferable that the second electrode comprise a portion electrically connected to an external terminal and a portion collecting electric current from the second conductivity-type semiconductor layer and that these portions be in contact with each other.

In the method of producing a photovoltaic device in accordance with the present invention, the step (5) preferably comprises bonding with an adhesive or melt-welding the opening of the second conductivity-type semiconductor layer and the peripheral part of the exposed part of the first conductivity-type semiconductor to the electric insulator layer around the connection hole.

The surface of the electric insulator layer is preferably made of a thermoplastic resin at least around the connection hole. Alternatively, the surface of the electric insulator layer is preferably coated with a hot-melt adhesive or a pressure-sensitive adhesive at least around the connection hole.

In the method of producing a photovoltaic device in accordance with the present invention, it is preferable that at least one of the steps (6) and (7) comprise connecting the electrode to the conductor layer with solder or conductive material.

The solder is preferably spherical solder or palletized solder.

It is preferable to further comprise preliminarily applying solder onto the surface of at least a part of the conductor layer to be soldered to the electrode prior to connecting the electrode to the conductor layer with solder.

It is preferable that the preliminarily applying solder comprise applying solder paste onto the surface of the conductor layer.

A second method for producing a photovoltaic device in accordance with the present invention comprises the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) bonding with an adhesive or melt-welding the opening of the second conductivity-type semiconductor layer and the peripheral part of the exposed part of the first conductivity-type semiconductor to the electric insulator layer around the connection hole to fix the photovoltaic element into the recess of the support; (6) connecting the second electrode to the second conductor layer with solder or conductive material; and (7) connecting the first electrode to a first conductor layer disposed on the backside of the support through the connection hole with solder or conductive material.

In the second method, the steps (5), (6) and (7) are performed simultaneously by pressing, while heating, the photovoltaic element, with solder or a conductive-material-containing paste placed between the second electrode and a part of the second conductor layer to be connected to the second electrode and between the first electrode and a part of the first conductor layer to be connected to the first electrode.

A third method for producing a photovoltaic device in accordance with the present invention comprises the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) bonding with an adhesive or melt-welding the opening of the second conductivity-type semiconductor layer and the peripheral part of the exposed part of the first conductivity-type semiconductor to the electric insulator layer around the connection hole to fix the photovoltaic element into the recess of the support; (6) electrically connecting the second electrode to the second conductor layer; and (7) connecting the first electrode to a first conductor layer disposed on the backside of the support through the connection hole with solder.

In the third method, the steps (5) and (7) are performed simultaneously by pressing the photovoltaic element in such a direction as to bring the opening of the second conductivity-type semiconductor layer and the peripheral part of the exposed part of the first conductivity-type semiconductor in contact with the electric insulator layer around the connection hole, with solder placed between the first electrode and a part of the first conductor layer to be soldered to the first electrode, while heating the solder and the electric insulator layer.

A fourth method for producing a photovoltaic device in accordance with the present invention comprises the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) disposing the photovoltaic element in the recess of the support such that the opening of the second conductivity-type semiconductor layer and a peripheral part of the exposed part of the first conductivity-type semiconductor are in contact with the electric insulator layer around the connection hole; (6) connecting the second electrode to the second conductor layer with solder; and (7) connecting the first electrode to a first conductor layer disposed on the backside of the support through the connection hole with solder.

In the fourth method, the step (7) comprises placing a first solder between the first electrode and a part of the first conductor layer to be soldered to the first electrode and heating the first solder to solder the first electrode to the first conductor layer and is performed before the step (6), and the step (6) comprises placing a second solder having a liquidus temperature lower than the solidus temperature of the first solder between the second conductor layer of the support and the second electrode of the photovoltaic element soldered to the first conductor layer by the step (7) and heating the second solder at a temperature lower than the solidus temperature of the first solder and not lower than the liquidus temperature of the second solder to solder the second electrode to the second conductor layer.

It is preferable that the diameter of the photovoltaic element be 0.5 to 2.0 mm.

It is preferable that the first solder be one or more spherical solder particles and that the diameter of the spherical solder particle be not greater than the diameter of the connection hole, not less than the depth of the connection hole, and 0.1 to 0.5 mm.

It is preferable that the second solder be a plurality of spherical solder particles and that the diameter of the spherical solder particle be 0.03 to 0.1 mm.

It is preferable that the liquidus temperature of the first solder be 200 to 300° C. and that the liquidus temperature of the second solder be 100 to 200° C.

It is preferable that the first solder contain not less than 90% by weight of tin.

It is preferable that the second solder contain 40 to 60% by weight of tin and a total of 60 to 40% by weight of indium and bismuth.

A photovoltaic device in accordance with the present invention comprises: a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed, a first electrode being formed on the exposed part of the first conductivity-type semiconductor, a second electrode being formed on a part of the surface of the second conductivity-type semiconductor layer; a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; and a first conductor layer disposed on the backside of the support, wherein the second electrode of the photovoltaic element disposed in the recess is electrically connected to the second conductor layer, and the first electrode is electrically connected to the first conductor layer through the connection hole.

It is preferable that at least either the second electrode and the second conductor layer or the first electrode and the first conductor layer be connected to each other with solder or conductive material.

The surface of the electric insulator layer around the connection hole preferably has a shape corresponding to the shape of the peripheral part of the exposed part of the first conductivity-type semiconductor and the opening of the second conductivity-type semiconductor layer.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE SEVERAL VIEWS OF THE DRAWING

FIG. 1 is a longitudinal sectional view illustrating a spherical photovoltaic element having an opening of a second conductivity-type semiconductor layer in accordance with the present invention.

FIG. 2 is a bottom view of the spherical photovoltaic element of FIG. 1.

FIG. 3 is a longitudinal sectional view illustrating another example of the spherical photovoltaic element having an opening of a second conductivity-type semiconductor layer in accordance with the present invention.

FIG. 4 is a longitudinal sectional view illustrating a step of applying a conductive ink onto the spherical photovoltaic element by an ink-jet printer for forming a first electrode in accordance with the present invention.

FIG. 5 is a bottom view of the spherical photovoltaic element with the conductive ink applied by the step of FIG. 4.

FIG. 6 is a longitudinal sectional view illustrating another example of the step of applying a conductive ink onto the spherical photovoltaic element by an ink-jet printer for forming a first electrode in accordance with the present invention.

FIG. 7 is a longitudinal sectional view illustrating still another example of the step of applying a conductive ink onto the spherical photovoltaic element by an ink-jet printer for forming a first electrode in accordance with the present invention.

FIG. 8 is a longitudinal sectional view illustrating a step of applying a conductive ink onto the spherical photovoltaic element by an ink-jet printer for forming a second electrode in accordance with the present invention.

FIG. 9 is a longitudinal sectional view illustrating the spherical photovoltaic element with the first and second electrodes formed in accordance with the present invention.

FIG. 10 is a bottom view of the spherical photovoltaic element of FIG. 9.

FIG. 11 is longitudinal sectional views illustrating a step of applying a conductive ink onto the spherical photovoltaic element by a dispenser for forming a first electrode in accordance with the present invention.

FIG. 12 is a longitudinal sectional view illustrating a step of applying a conductive ink onto the spherical photovoltaic element by a dispenser for forming a second electrode in accordance with the present invention.

FIG. 13 is a longitudinal sectional view illustrating another example of the spherical photovoltaic element with the first and second electrodes formed in accordance with the present invention.

FIG. 14 is a bottom view of the spherical photovoltaic element of FIG. 13.

FIG. 15 is a longitudinal sectional view illustrating still another example of the spherical photovoltaic element with the first and second electrodes formed in accordance with the present invention.

FIG. 16 is a plane view of the spherical photovoltaic element of FIG. 15.

FIG. 17 is a bottom view of the spherical photovoltaic element of FIG. 15.

FIG. 18 is a plane view of a first embodiment of a support in accordance with the present invention.

FIG. 19 is a sectional view of the support taken on line A-B of FIG. 18.

FIG. 20 is a longitudinal sectional view of a second embodiment of the support in accordance with the present invention.

FIG. 21 is a longitudinal sectional view of a third embodiment of the support in accordance with the present invention.

FIG. 22 is a longitudinal sectional view of a fourth embodiment of the support in accordance with the present invention.

FIG. 23 is a longitudinal sectional view illustrating the spherical photovoltaic element disposed at a predetermined position inside a recess of the support in accordance with the present invention.

FIG. 24 is a longitudinal sectional view illustrating another example of the spherical photovoltaic element disposed at a predetermined position inside a recess of the support in accordance with the present invention.

FIG. 25 is longitudinal sectional views illustrating a step of disposing the spherical photovoltaic element at a predetermined position inside the recess of the support in accordance with the present invention.

FIG. 26 is a longitudinal sectional view illustrating the spherical photovoltaic element with the second electrode and a second conductor layer connected with solder in accordance with the present invention.

FIG. 27 is a longitudinal sectional view illustrating the spherical photovoltaic element with the first electrode and a first conductor layer connected with solder in accordance with the present invention.

FIG. 28 is longitudinal sectional views illustrating a step of connecting the electrodes to the conductor layers with solder simultaneously with melt-welding of the bottom of the spherical photovoltaic element to the electric insulator layer at circumferential part of a connection hole in accordance with the present invention.

FIG. 29 is longitudinal sectional views illustrating a step of connecting the first electrode to the first conductor layer with a first spherical solder in accordance with the present invention.

FIG. 30 is longitudinal sectional views illustrating another example of the step of connecting the first electrode to the first conductor layer with a first spherical solder in accordance with the present invention.

FIG. 31 is longitudinal sectional views illustrating a step of connecting the second electrode to the second conductor layer with a second spherical solder in accordance with the present invention.

FIG. 32 is a longitudinal sectional view illustrating a step of preliminarily applying solder to the first conductor layer in accordance with the present invention.

FIG. 33 is a longitudinal sectional view illustrating spherical photovoltaic elements disposed in recesses of a support in a conventional photovoltaic device.

FIG. 34 is longitudinal sectional views illustrating a step of forming electrodes on a conventional spherical photovoltaic element.

### DETAILED DESCRIPTION OF THE INVENTION

A method of producing a photovoltaic device in accordance with the present invention enables a reduction in electrical resistance and its variation of the connected part between a first conductivity-type semiconductor (hereinafter referred to as first semiconductor) of a spherical element of a spherical photovoltaic device and a first conductor layer and the connected part between a second conductivity-type semiconductor layer (hereinafter referred to as second semiconductor layer) and a second conductor layer. The production method in accordance with the present invention further makes it possible to firmly fix the spherical element to a predetermined position of a support.

An essential feature of the production method of the present invention for reducing the electrical resistance and its variation is to prepare a spherical element in which each of the first semiconductor and the second semiconductor layer has an electrode. This production method prepares a support composed integrally of an electric insulator layer and a second conductor layer, electrically connects the second semiconductor layer of the spherical element disposed on this support to the second conductor layer, and further electrically connects the first semiconductor to a first conductor layer through a connection hole formed in the electric insulator layer.

One method of forming an electrode on a semiconductor is a method of applying a conductive ink onto a semiconductor and subjecting it to a heat treatment at high temperatures of 550 to 750° C. to form a conductive coating. The resultant electrode has extremely small contact resistance to the underlying semiconductor layer, and moreover, has small contact resistance to the conductor layer. Therefore, just bringing the electrode in direct contact with the conductor layer enables the semiconductor to be electrically connected to the conductor layer with relatively low resistance. The present invention performs this electrode formation step at such high temperatures before the step of disposing the spherical element on the support. This eliminates the need to expose the electric insulator layer to high temperatures of 500 to 577° C. of the previously described prior art, making it possible to electrically connect the semiconductor of the spherical element to the conductor layer in a reliably manner without fear of softening, melting or decomposition of the electric insulator layer made of resin.

According to the present invention, just bringing the electrode formed on the semiconductor in mechanical contact with the conductor layer at ordinary temperatures enables electrical connection between the semiconductor and the conductor layer. In order to further reduce the electrical resistance of the connected part of the semiconductor and the conductor layer and achieve more reliable electrical connection, it is preferable to join the electrode formed on the semiconductor and the corresponding conductor layer with solder, conductive material or the like. In this case, since the electric insulator layer has only to withstand the typical temperatures of soldering (approximately 100 to 350° C.) or the typical curing temperatures of conductive-material-containing paste (room temperature to approximately 200° C.), it is easy to select a material of the electric insulator layer.

In the present invention, the spherical element is disposed in the recess of the support such that the bottom of the spherical element (the opening of the second semiconductor layer and the exposed part of the first semiconductor) is in contact with the electric insulator layer around the connection hole. In doing this, by fitting the location of the second semiconductor layer slightly higher than the opening of the second semiconductor layer to the opening of the second conductor layer at the bottom of the recess of the support, the effect of fixing the spherical element to the predetermined position inside the recess of the support can be obtained to some extent. However, in order to more firmly fix the spherical element to the support, it is effective to join the bottom of the spherical element to the electric insulator layer around the connection hole by bonding with an adhesive, melt-weldinq or the like.

As described above, by connecting the semiconductor to the conductor layer with solder, conductive material or the like, they are mechanically joined, and hence the spherical element can be secured to the support more firmly. It is noted, however, that if an attempt is made to directly connect the semiconductor to the conductor layer with solder, conductive material or the like without forming an electrode, they cannot be joined firmly enough and the effect of reducing the electrical resistance of the connected part is hardly obtained.

In the following, embodiments of each step of the production method of the present invention will be specifically described.

1. Step (1)

First, a spherical first semiconductor, which is the base of a spherical element, is prepared. The spherical first semiconductor can be produced, for example, by a method disclosed in U.S. patent publication No. 2002/0096206 A1, published Jul. 25, 2002, which is incorporated herein by reference in its entirety. According to this method, a polycrystalline silicon melt of p-type semiconductor is stored in a crucible, the melt is dropped from a nozzle into a gaseous phase, and the dropped melt becomes fine particles as it drops while cooled. The spherical first semiconductor can also be produced, for example, by dropping p-type polycrystalline silicon particles containing a trace amount of boron in a vacuum while heating them until they melt and then cooling them. By these methods, a spherical polycrystalline or single-crystal p-type semiconductor having good crystallinity can be obtained.

Subsequently, a second semiconductor layer is formed on the surface of the spherical first semiconductor. For example, phosphorous oxychloride may be used as a diffusion source, and the spherical first semiconductor is subjected to a heat treatment at 800 to 900° C. for 10 to 30 minutes to diffuse phosphorous on the surface thereof, whereby an n-type semiconductor layer having a thickness of approximately 0.5 to 1.0 μm is formed. The second semiconductor layer may be formed by another method in which a thin n-type polycrystalline silicone layer is formed by CVD utilizing, for example, a mixed gas of phosphine and silane.

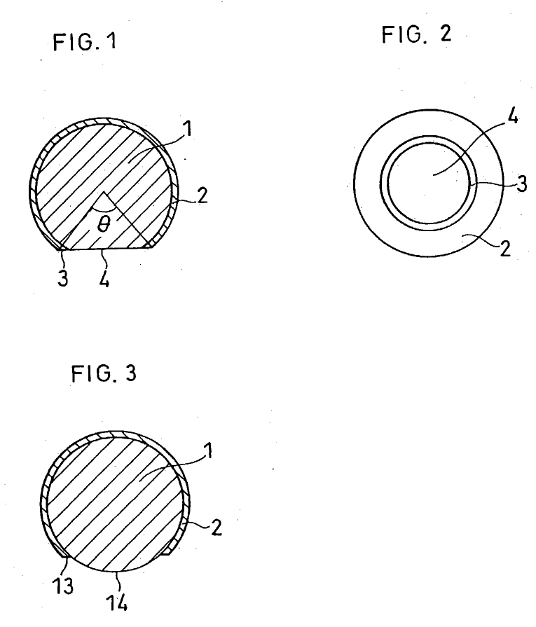

After the thin second semiconductor layer is formed on the surface of the spherical first semiconductor as described above, an opening is formed in the second semiconductor layer to expose a part of the first semiconductor. The opening can be formed, for example, by a method of removing a part of the spherical element by grinding or the like. FIG. 1 is a longitudinal sectional view of a spherical element which is processed by this method, and FIG. 2 is a bottom view of the spherical element. A part of the spherical element in which the surface of a spherical first semiconductor 1 is coated with a second semiconductor layer 2 is cut off, so that an opening 3 of the second semiconductor layer 2 is formed around a circular exposed part 4 of the first semiconductor 1 at the circular flat cut section.

The opening of the second semiconductor layer can also be formed by a method of masking the surface of the spherical element except a part thereof with paraffin or the like and removing the unmasked part of the second semiconductor layer by etching. FIG. 3 is a longitudinal sectional view of a spherical element which is processed by this method. A part of the second semiconductor layer 2 coating the surface of the first semiconductor 1 is removed by etching, so that an exposed part 14 of the first semiconductor 1 is formed inside an opening 13 of the second semiconductor layer. Since the second semiconductor layer is very thin, the outer shape of the processed spherical element remains almost unchanged from the original shape before the processing. Also, the surface of the exposed part 14 of the first semiconductor has almost the same curve as the spherical first semiconductor 1.

Although it is preferable that the first semiconductor be completely spherical, it may be substantially spherical. The spherical first semiconductor of the present invention may be composed of a core coated with the first semiconductor layer, and the substantially spherical first semiconductor may be hollow near the center thereof. The diameter of the spherical element is preferably 0.5 to 2 mm and more preferably 0.8 to 1.2 mm. This makes it possible to obtain a spherical element which uses sufficiently reduced amounts of expensive material such as high-purity silicon, which generates large amounts of electric power, and which is easy to handle. The angle formed by connecting the central point of the spherical element to opposing two points on the circumference of the opening (central angle designated by θ in FIG. 1) is preferably 45 to 90° and more preferably 60 to 90°. This enables a sufficient reduction in the amount of material waste produced by cutting and further ensures adequate area of the opening necessary for the electrical connection between the first semiconductor and the first conductor layer.

Although the above embodiments have described the spherical element in which the first semiconductor is a p-type semiconductor and the second semiconductor layer is an n-type semiconductor layer, the spherical element may comprise an n-type first semiconductor and a p-type second semiconductor layer. Although the above embodiments have described the spherical element comprising a crystal silicon semiconductor, the spherical element may comprise another material such as a compound semiconductor and also comprise an amorphous material in addition to single-crystal and polycrystal. The spherical element may also have a structure such as a pin type having a non-doped layer at the interface between the first semiconductor and the second semiconductor layer, an MIS (metal-insulator-semiconductor) type, a Schottky barrier type, a homo-junction type, and a hetero-junction type.

In this way, it is possible to prepare a plurality of substantially spherical photovoltaic elements, each comprising a spherical first semiconductor and a second semiconductor layer covering the surface of the first semiconductor, the second semiconductor layer having an opening through which a part of the first semiconductor is exposed.

2. Step (2)

A first electrode can be formed, for example, by applying a conductive ink onto the exposed surface of the first semiconductor of the spherical element by an ink-jet printer and subjecting it to a heat treatment at 500 to 750° C. (ink-jet method). Further, the first electrode can also be formed by applying a conductive ink onto the exposed surface by a dispenser and subjecting it to a heat treatment (dispenser method).

As the conductive ink, an ink prepared by dispersing glass frit and conductive material in an organic solvent or the like may be used.- As the conductive material, it is preferable to use a mixture of a silver (Ag) fine powder and an aluminum (Al) fine powder when the first semiconductor is a p-type semiconductor and to use a mixture of a silver fine powder and a phosphorous or phosphorous compound fine powder when the first semiconductor is an n-type semiconductor.

The above-described heat treatment causes formation of an alloy layer of the first semiconductor and the conductive material contained in the conductive ink on the surface of the first semiconductor onto which the conductive ink is applied, thereby increasing the conductivity of the interface between the electrode-forming surface of the first semiconductor and the coating of the conductive ink. The heat treatment also allows glass frit to melt and function as a binder. This produces a conductive coating having small contact resistance and resistivity, and excellent mechanical strength. The first electrode is composed of one or more of the conductive coatings thus formed. The shape of the first electrode is not particularly limited, and the first electrode may have various shapes such as a circle, an oval, a polygon and an assembly of dots.

Next, the method of forming the first electrode by the ink-jet method will be described in detail. As the conductive ink, the following dispersion may be used, for example. A mixture of a silver fine powder and an aluminum fine powder, each powder having an average particle diameter of 0.1 to 0.2 μm, is mixed with glass frit composed of B₂O₃—PbO—ZnO glass having an average particle diameter of 0.1 to 0.2 μm in a weight ratio of 1:1. This mixture is added, while being stirred, to a dispersion medium of butyl acetate such that its viscosity becomes approximately 0.05 Pa·s.

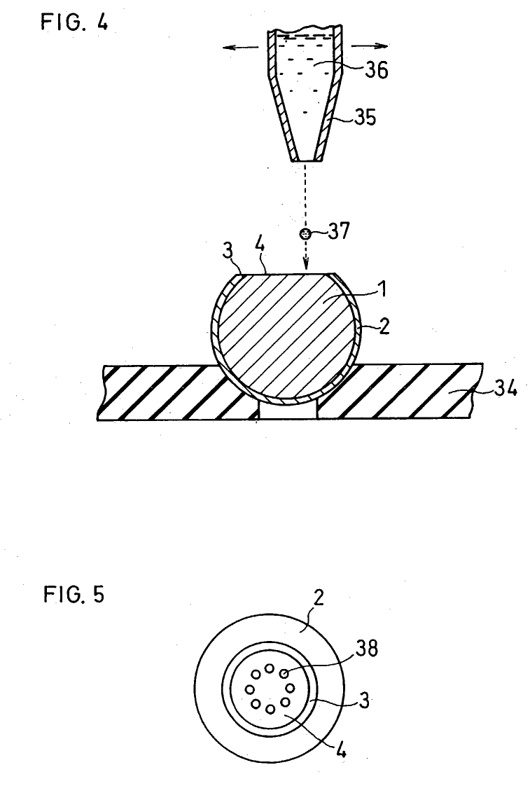

FIG. 4 illustrates a step of applying the conductive ink onto the exposed surface of the first semiconductor by an ink-jet printer, and FIG. 5 is a bottom view of the spherical element with the conductive ink applied by the step of FIG. 4. The spherical element as illustrated in FIG. 1, which has the flat exposed part 4 of the first semiconductor 1, is sucked by vacuum chuck and fixed to a mount 34 such that the exposed part 4 faces upward. An ink-jet head 35 is placed up in the direction perpendicular to the exposed part 4 of the first semiconductor 1. The ink-jet head 35 is capable of traveling in the directions of X-Y axes two-dimensionally, and its specific traveling pattern is pre-input in a computer.

From the ink-jet head 35, a fine droplet 37 of a conductive ink 36 is jetted to the direction of the arrow, and the droplet 37 adheres to the exposed part 4 of the first semiconductor almost perpendicularly thereto. If the conductive ink droplet 37 is jetted, for example, in an amount of approximately 10 picoliter from the ink-jet head 35, a coating 38 having a diameter of approximately 50 μm and a thickness of approximately 5 am is formed. While moving the ink-jet head 35, the conductive ink droplet 37 is continuously jetted to the exposed part 4 such that the coating 38 in the form of a circle is formed at a plurality of locations (eight locations) almost equally spaced on the circumference of a circle 300 μm in diameter within the exposed part 4. Subsequently, these coatings 38 are subjected to a heat treatment at 500 to 750° C. for 5 to 30 minutes to form the first electrode composed of eight minute conductive coatings. The step of applying the conductive ink may be performed using an ink-jet head of any of a piezo type and a thermal type.

The method as illustrated in FIG. 4 may also be applicable to formation of the first electrode on the spherical element as illustrated in FIG. 3, in which the exposed part of the first semiconductor is curved. However, in this case, since the surface to which the conductive ink droplet is to adhere is not perpendicular to the jetting direction of the droplet, the adhered droplet does not necessarily become circular, but tends to have irregular shapes such as an oval or oblong because of running of the droplet. In order to heighten the accuracy of the dimensional shape of the first electrode, it is necessary to suppress the running of the adhered droplet and form a coating having a uniform shape.

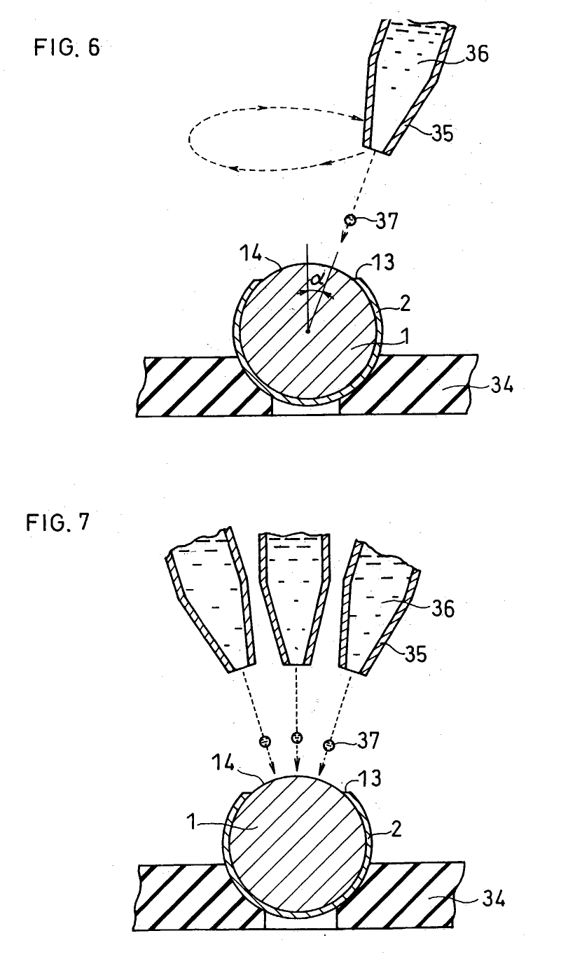

For this purpose, employing, for example, a method as illustrated in FIG. 6 is effective. The ink-jet head 35 is placed at a position on the axis line which forms an angle a with the line passing through the center of the first semiconductor 1 and the center of the exposed part 14. In other words, the ink-jet head 35 is arranged at such a position that the conductive ink droplet 37 perpendicularly adheres to the exposed part 14 of the first semiconductor 1. Such an arrangement makes it possible to form a coating having a uniform shape without allowing the conductive ink droplet 37 to run even when the surface to which the droplet 37 is to adhere is curved. For example, in order to cause the conductive ink droplet 37 to perpendicularly adhere to the circumference of a circle 150 μm in radius centered on the center of the exposed part 14 of the first semiconductor 1, the ink-jet head 35 is arranged on the axis line of α=17°. This arrangement makes it possible to form a coating which is almost completely circular.

Although the above embodiments have described the use of one ink-jet head, a plurality of ink-jet heads 35 may be arranged, if necessary, on the lines perpendicular to the surfaces to which the droplet 37 of the conductive ink 36 is to adhere in order to cause the conductive ink droplets 37 to simultaneously adhere to a plurality of locations on the above-mentioned circumference. This significantly reduces the time necessary for forming the electrode and further enables formation of the electrode having higher accuracy.

Although the above embodiments have described the methods for forming the first electrode composed of eight conductive coatings arranged on the circumference of the same circle, the number, shape, size, arrangement, etc. of the conductive coating may be arbitrarily changed as needed. Also, a conductive coating having a desired shape may be formed by connecting a plurality of conductive ink droplets to form a coating having a desired shape such as a circle, an oval, a polygon, a line or a ring and subjecting it to a heat treatment. The first electrode may be composed of a single conductive coating or a plurality of conductive coatings arranged in a predetermined pattern such as an arrangement on the circumference of the same circle.

3. Step (3)

A second electrode can be formed, for example, by applying a conductive ink onto a part of the surface of the second semiconductor layer, preferably an outer surface of the second semiconductor layer close to the opening, by an ink-jet printer and subjecting it to a heat treatment at 550 to 750° C. (ink-jet method). Further, the second electrode can also be formed by applying a conductive ink onto the above-described surface by a dispenser and subjecting it to a heat treatment at 550 to 750° C. (dispenser method).

As the conductive ink, an ink prepared by dispersing a mixed fine powder of glass frit and conductive material such as silver in an organic solvent or the like may be preferably used. When the second semiconductor layer is a p-type semiconductor, it is preferable to use a conductive ink that uses a mixture of a silver fine powder and an aluminum fine powder as the conductive material instead of the silver.

When the spherical element is composed mainly of silicon, the above-described heat treatment causes formation of an alloy layer of silver and silicon at the interface between the coating of the conductive ink and the applied surface of the first semiconductor. The heat treatment also allows glass frit to melt and function as a binder. This produces a conductive coating having small contact resistance and resistivity, and excellent mechanical strength.

The shape of the conductive coating is not particularly limited, and the conductive coating may have various shapes such as a circle and an oval, or a ring, a polygon and a line comprised of connected circles or ovals. The second electrode can be formed by aligning a plurality of these conductive coatings on the outer surface of the second semiconductor layer. The conductive coatings are preferably scattered on the circumference of the same circle on the outer surface of the second semiconductor layer. Further, the second electrode may be composed of a single conductive coating formed, for example, in the form of a ring or a line on the outer surface of the second semiconductor layer.

Next, the method of forming the second electrode by the ink-jet method will be specifically described. The conductive ink is prepared, for example, as follows. A silver fine powder having an average particle diameter of 0.1 to 0.2 μm is mixed with a silver phosphate fine powder having an average particle diameter of 0.1 to 0.2 μm in a weight ratio of 1:1. Then, 100 parts by weight of this mixture is added to 100 parts by weight of glass frit composed of B₂O₃—PbO—ZnO glass having an average particle diameter of 0.1 to 0.2 μm. The resultant mixture is dispersed in butyl acetate such that its viscosity becomes approximately 0.05 Pa·s.

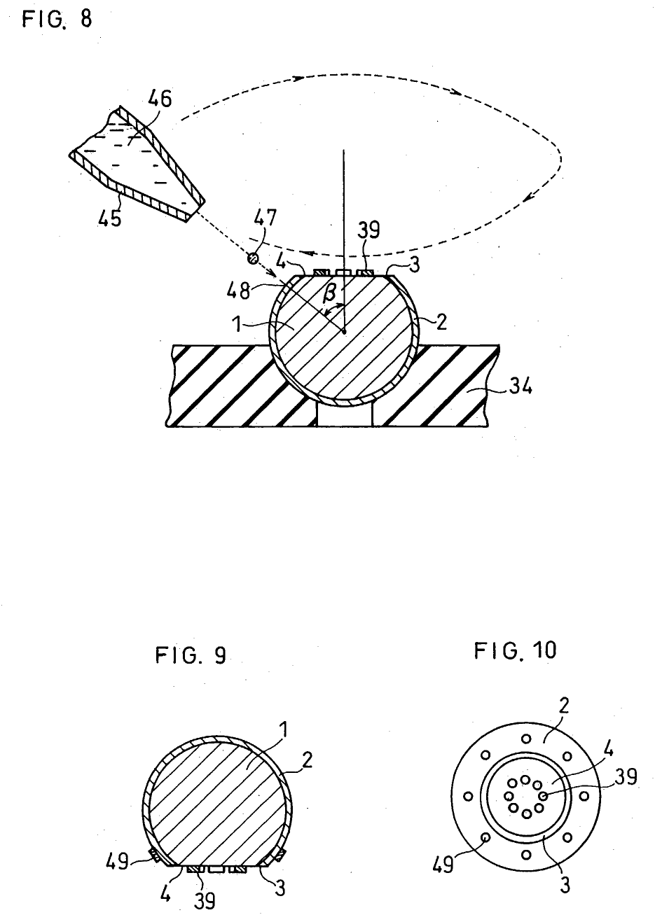

FIG. 8 illustrates a step of applying the conductive ink for forming the second electrode by the ink-jet printer. The spherical element having the first electrode formed by the step (2) is fixed to the mount 34 by vacuum chuck such that the exposed part 4 of the first semiconductor 1 faces upward. An ink-jet head 45 is placed on the axis line perpendicular to an electrode-forming surface 48 of the second semiconductor layer 2. The ink-jet head 45 is capable of freely traveling in the directions of X-Y axes two-dimensionally, and its specific traveling pattern is pre-input in a computer.

For example, an angle β which the line passing through the center of the first semiconductor 1 and the center of the exposed part 4 forms with the axis line passing through the center of the ink-jet head is made approximately 45°. Then, the central part of a droplet 47 of a conductive ink 46 jetted from the ink-jet head 45 can almost perpendicularly adhere to the electrode-forming surface 48 of the second semiconductor layer 2 which is on the circumference of a circle approximately 120 μm away from the opening 3 of the second semiconductor layer 2. By jetting approximately 7 picoliter of the conductive ink droplet 47 from the ink-jet head 45, a coating of the conductive ink having a diameter of approximately 40 μm and a thickness of approximately 4 μm is formed.

While moving the ink-jet head 45 in the direction of the arrow of FIG. 8, the above-described coating is formed at a plurality of locations (eight locations) on the circumference of the same circle on the surface of the second semiconductor layer. Subsequently, the spherical element with these coatings is subjected to a heat treatment at 500 to 750° C. for 5 to 30 minute. In this way, the second electrode composed of the plurality of conductive coatings arranged on the circumference of the same circle on the surface of the second semiconductor layer is formed.

Although FIG. 8 illustrates the method of applying the conductive ink by one ink-jet head 45, a plurality of ink-jet heads may be arranged on the axis lines perpendicular to the surfaces to which the conductive ink droplet is to adhere. This arrangement allows the plurality of ink-jet heads to simultaneously jet the conductive ink droplets perpendicularly to the plurality of predetermined surfaces, so that the time necessary for forming the second electrode can be significantly reduced. Further, since this arrangement makes it easy to attach the conductive ink droplet to the predetermined position, electrodes having a desired shape can be formed at predetermined locations with higher accuracy.

FIG. 9 is a longitudinal sectional view of a typical example of the spherical element with the first and second electrodes formed by the ink-jet method, and FIG. 10 is a bottom view of the spherical element. Eight conductive coatings 39 are substantially circular and have a diameter of approximately 50 μm. These conductive coatings 39 are arranged on the circumference of the same circle on the exposed surface 4 of the first semiconductor 1 of the spherical element as illustrated in FIG. 1, to form the first electrode. Eight conductive coatings 49 are substantially circular and have a diameter of approximately 40 μm. These conductive coatings 49 are arranged on the circumference of a circle on the second semiconductor layer 2 approximately 100 μm away from the opening 3 of the second semiconductor layer, to form the second electrode.

The above embodiments of steps (2) and (3) have described the methods of electrode formation by the ink-jet method, but the following will describe methods of electrode formation by the dispenser method. The dispenser method uses a dispenser as a device for applying the conductive ink to the predetermined position. A dispenser is a device that discharges a very small amount of liquid in prescribed amounts, and by applying a small pressure to liquid filled in a narrow nozzle by pressurized air or the like, the dispenser pushes out a very small amount of liquid from the tip end of the nozzle to apply the liquid to a desired surface.

The dispenser method is suited for formation of an electrode composed of one or a few conductive coatings, because the amount of liquid discharged at one time is greater than that according to the ink-jet method. Also, the dispenser method uses a conductive ink having a relatively high viscosity of 10 to 300 Pa·s, thereby enabling formation of a thick conductive coating.

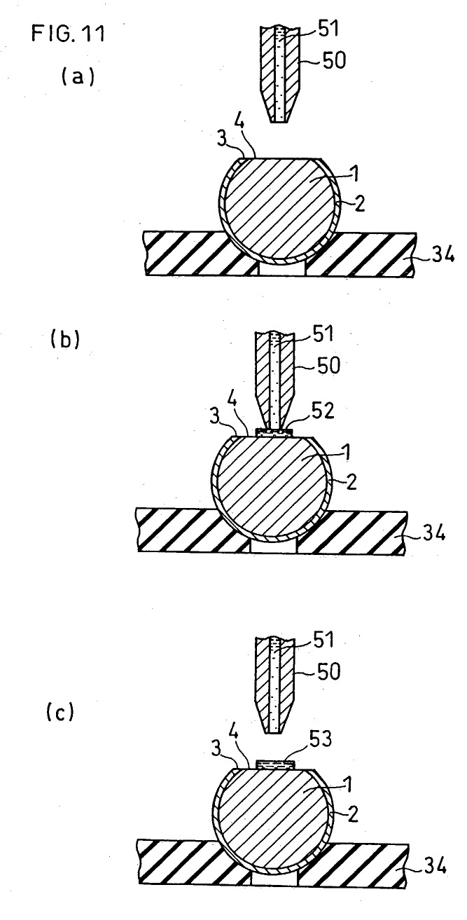

FIG. 11 illustrates a step of applying the conductive ink for forming the first electrode by a dispenser. First, the spherical element as illustrated in FIG. 1 is secured to the mount 34 by vacuum chuck such that the exposed part 4 of the first semiconductor 1 faces upward. A conductive ink 51 is charged into the dispenser having a nozzle 50 with an internal diameter of 100 μm. As illustrated in FIG. 11(a), the tip end of the nozzle 50 is placed at a position which is close to the exposed part 4 of the first semiconductor 1 and is on the axis line perpendicular to the exposed part 4. Subsequently, the tip end of the nozzle 50 is brought closer to the central part (first-electrode-forming surface) of the exposed part 4 such that there is an interval of 50 to 300 mm between them. In this state, by pressing the conductive ink 51 in the nozzle 50 by air pressure of 150 kPa at 100 msec., about 600 picoliter of the conductive ink 51 is squeezed out of the tip end of the nozzle 50 such that the squeezed ink 52 comes in contact with the first-electrode-forming surface as illustrated in FIG. 11(b). Then, by moving the nozzle 50 away from the exposed part 4 of the first semiconductor 1, the ink 52 squeezed out of the tip end of the nozzle 50 is applied to the exposed part 4. Accordingly, as illustrated in FIG. 11(c), a circular coating 53 of the conductive ink having a diameter of approximately 200 μm is formed on the central part of the exposed part 4 of the first semiconductor.

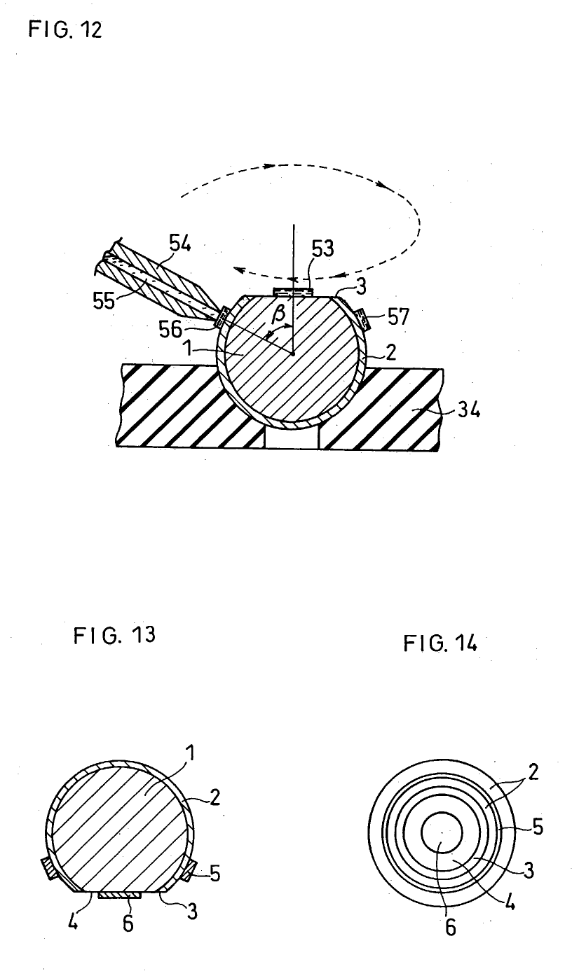

Subsequently, in order to form the second electrode, the conductive ink is applied onto the second semiconductor layer by a dispenser. In FIG. 12, a conductive ink 55 is charged into a dispenser having a nozzle 54 with an internal diameter of 100 μm, and an angle β which the line passing through the center of the first semiconductor 1 and the center of the exposed part 4 forms with the axis line passing through the center of the nozzle 54 is approximately 45°. The tip end of the nozzle 54 is disposed close to the second-electrode-forming-surface of the second semiconductor layer 2 on the circumference of a circle approximately 120 μm away from the opening 3 of the second semiconductor layer 2 such that there is an interval of 50 to 300 μm therebetween. In this state, while moving the nozzle 54 in the direction of the arrow, by pressing the conductive ink 55 in the nozzle 54 by air pressure of 100 kPa, a very small amount of the conductive ink 55 is squeezed out of the tip end of the nozzle 54 so that the squeezed conductive ink 56 is applied to the second-electrode-forming surface. Accordingly, a coating 57 of the conductive ink having a ring-like shape and a width of approximately 100 μm is formed on the outer surface of the second semiconductor layer 2.

The spherical element with the coatings 53 and 57 of the conductive ink formed in the above manner is subjected to a heat treatment of 500 to 750° C. for 5 to 30 minutes, whereby the first electrode and the second electrode can be formed simultaneously. FIG. 13 is a longitudinal sectional view of the spherical element with the electrodes formed thereon, and FIG. 14 is a bottom view of the spherical element. The first electrode 6 and the second electrode 5 of the spherical element are formed by subjecting the coatings 53 and 57 to the heat treatment, respectively, and each of them is composed of a single conductive coating.

Each of the electrodes as described above serves as a pad part that is electrically connected to an external terminal either directly or with solder, conductive material or the like, and it also serves as a contact part that is directly connected to the semiconductor.

In many cases, the second semiconductor layer is composed of an extremely thin layer in order to heighten the photoelectric conversion efficiency of the spherical element, and its sheet resistivity is therefore extremely large. Thus, the second electrode composed only of the above-described pad-contact part does not necessarily have a sufficient function of collecting current from the distant part of the second semiconductor layer from the second electrode. In order to enhance this current collecting function, it is effective that the second electrode (or the conductive coating constituting the second electrode) further has a grid part which is formed in contact with the pad-contact part for collecting current from a large area of the surface of the second semiconductor layer with low resistance. The area of the grid part is preferably kept at a minimum so as not to substantially decrease the area of the effective light-receiving surface of the second semiconductor layer.

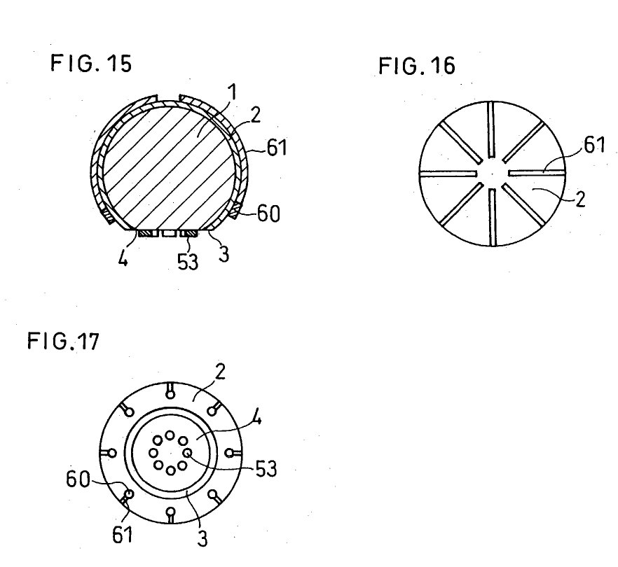

FIG. 15 is a longitudinal sectional view of a spherical element with the second electrode having the grid part. FIG. 16 is a plane view of the spherical element, and FIG. 17 is a bottom view thereof. This spherical element has the first electrode comprising the conductive coatings 53 obtained by subjecting the coatings 38 of FIG. 5 to the heat treatment and the second electrode. Eight conductive coatings 60 constituting the pad-contact part of the second electrode are formed on the circumference of the same circle on the outer surface of the second semiconductor layer 2 close to the exposed part 4 of the first semiconductor 1. Each of the conductive coatings 60 is connected to a linear grid part 61 which extends upward along the second semiconductor layer 2. In this way, by forming linear grid parts over a large area of the surface of the second semiconductor layer, it is possible to effectively collect current from the second semiconductor layer.

The above embodiments of steps (2) and (3) have described the methods of applying the conductive ink to the predetermined position of the fixed spherical element while moving the nozzle of the ink-jet head or dispenser in the prescribed pattern. However, it is also possible to form the coating of the conductive ink while moving both of the spherical element and the nozzle of the ink-jet head or dispenser, or moving only the spherical element.

The above embodiments have described the methods of forming the first electrode in step (2) and thereafter forming the second electrode in step (3), but the forming order of the first electrode and the second electrode may be reversed. Also, the first and second electrodes may be formed simultaneously by forming coatings for the first and second electrodes either successively or simultaneously and thereafter subjecting the coatings for both electrodes to the heat-treatment simultaneously.

4. Step (4)

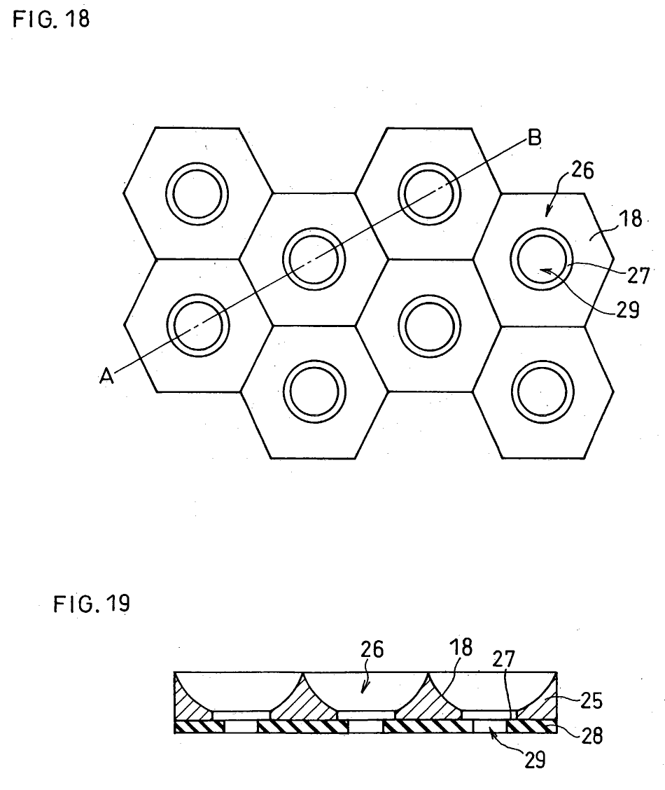

FIG. 18 is a partial plane view of a typical example of a support prepared in this step, and FIG. 19 is a sectional view taken on line A-B of FIG. 18. The support comprises an electric insulator layer 28 having circular connection holes 29 and a second conductor layer 25 having a plurality of recesses 26. Each recess 26 narrows toward the bottom, and its lower opening edge is circular while its upper opening edge is hexagonal. The respective upper opening edges are adjacent to one another, and the respective recesses 26 are formed in the form of a honeycomb. The second conductor layer. 25 is formed on the electric insulator layer 28 except circumferential parts 27 of the connection holes 29, and the electric insulator layer 28 is exposed at the circumferential parts 27 of the connection holes 29. In step (5) which will be described later, the spherical element is disposed in each recess 26 such that the opening of the second semiconductor layer and the exposed part of the first semiconductor are in contact with the exposed part of the electric insulator layer 28. An inner surface 18 of the second conductor layer 25 functions as an external electrode in electrical connection with the second semiconductor layer of the spherical element.

If the inner surface 18 of the second conductor layer 25 is made reflective, it serves as a reflecting mirror, leading to an increase in the light-gathering efficiency and a significant improvement in output of the photovoltaic device. The inner surface of the second conductor layer can be made reflective, for example, by polishing it to a mirror-smooth state.

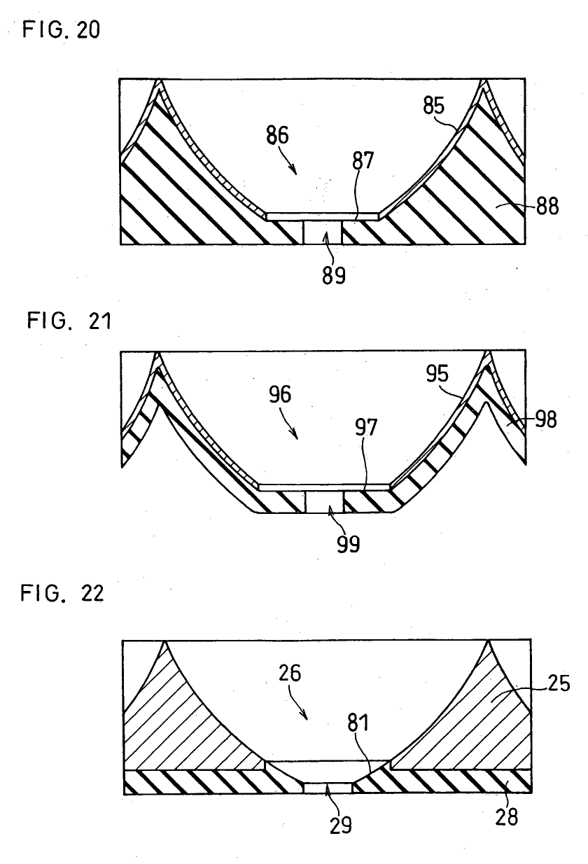

The support of FIG. 19 is produced by laminating a resin sheet such as polycarbonate to the second conductor layer of a thick plate such as aluminum or stainless steel in which a plurality of recesses are formed by cutting or the like. However, the support may take other various forms. The support of FIG. 20 is produced by molding an electric insulator layer 88, made of resin, which has a plurality of recesses 86, each recess having a connection hole 89, and forming a second conductor layer 85 composed of a thin metallic film such as aluminum on the electric insulator layer 88 except the connection holes 89 and circumferential parts 87 of the connection holes 89 by vacuum deposition or the like. Instead of the above-mentioned thin metallic film, metallic foil such as aluminum foil having openings slightly larger than the connection holes may be bonded as the second conductor layer to the inner surfaces of the recesses by thermo compression bonding or the like, to form a support having the same structure. The use of a mirror-finished metallic foil or a thin metallic film as the second conductor layer allows the inner surfaces of the recesses of the support to function as reflecting mirrors.

The support of FIG. 21 is prepared as follows. An aluminum foil sheet having a plurality of holes slightly larger than connection holes 99 is used as a second conductor layer 95, and a resin sheet having a plurality of holes serving as the connection holes 99 is used as an electric insulator layer 98. These two sheets are aligned and joined with each other by thermo compression bonding or the like to form a sheet in which the electric insulator layer is exposed at circumferential parts 97 of the connection holes 99. The resultant sheet is pressed to form a plurality of recesses 96.

The support of FIG. 22 is produced by changing a part of the support of FIG. 19. The surface shape of the electric insulator layer 28 at a circumferential part 81 of the connection hole 29 is changed so as to correspond to the shape of the exposed part of the first semiconductor and the opening of the second semiconductor layer of the spherical element. This support is specifically designed for spherical elements such as the one of FIG. 3 in which the exposed part of the first semiconductor is curved, and the surface shape of the electric insulator layer 28 at the circumferential part 81 of the connection hole 29 is changed accordingly. Such design facilitates placement of the spherical element to the predetermined position in the recess of the support in the following step (5).

In this way, it is possible to prepare a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses.

5. Step (5)

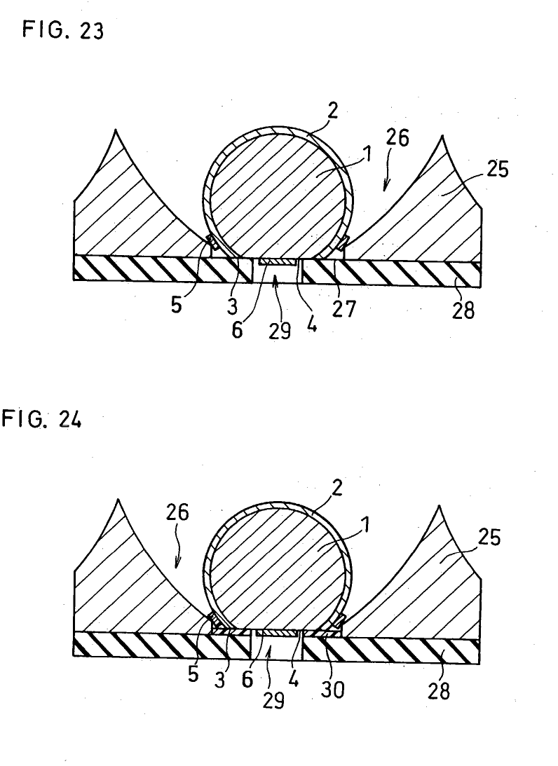

In step (5), the spherical element with the electrodes formed in the steps (2) and (3) is disposed at the predetermined position of the recess of the support prepared in the step (4). For example, the support as illustrated in FIG. 19 and the spherical element as illustrated in FIG. 13 are prepared. The spherical element is pressed in the bottom of the recess 26 of the support such that the outer surface of the second semiconductor layer 2 close to the opening 3 is fitted into the opening of the second conductor layer 25 and that the opening 3 of the second semiconductor layer and the exposed part 4 of the first semiconductor are in contact with the electric insulator layer at the circumferential part 27 of the connection hole 29. Accordingly, as illustrated in FIG. 23, the spherical element is disposed in the recess 26 of the support while the exposed part 4 of the first semiconductor is reliably insulated from the second semiconductor layer 2 by the electric insulator layer 28.

In case of misalignment of the spherical element where the part extending across the opening of the second semiconductor layer and the exposed part of the first semiconductor comes in contact with the edge or its vicinity of the opening of the second conductor layer, or in case of deviation of the properly placed spherical element from the predetermined position due to insufficient fixing, the first semiconductor and the second semiconductor layer will be short-circuited through the second conductor layer.

As illustrated in FIG. 23, by fitting the outer surface of the spherical element into the opening of the second conductor layer, the edge or its vicinity of the opening of the second conductor layer 25 comes in contact with the ring-like second electrode 5 on the outer surface of the second semiconductor layer closed to the opening 3. This contact makes it possible to electrically connect the second conductor layer and the second semiconductor layer, since the contact resistance between the second conductor layer and the second electrode is sufficiently small.

In order to fix the spherical element to the predetermined position inside the recess of the support, it is preferable that the opening of the second semiconductor layer and the peripheral part of the exposed part of the first semiconductor be bonded with an adhesive or melt-welded to the electric insulator layer at the circumferential part of the connection hole. FIG. 24 illustrates the spherical element that is fixed to the predetermined position in the recess 26 of the support with an adhesive 30. The spherical element is bonded by applying the adhesive 30, such as a solvent-type adhesive or an epoxy-type thermosetting adhesive, on the surface of the electric insulator layer 28 around the connection hole 29 and heating the spherical element that is pressed into the predetermined position in the recess 26 for drying or curing the adhesive.

Another preferable method for fixing the spherical element is as follows. A support is prepared, using an electric insulator layer composed of a thermoplastic resin or an electric insulator layer that is coated with a thermoplastic resin or a hot-melt adhesive at least at the circumferential parts of the connection holes. The spherical element is pressed, while being heated, against the bottom of the recess of the support to melt-weld the opening of the second semiconductor layer and the exposed part of the first semiconductor to the electric insulator layer at the circumferential part of the connection hole. This method enables the spherical element to be firmly fixed to the predetermined position of the recess of the support in a short period of time. The above-mentioned coating layer can be formed, for example, by a method of spraying a dispersion of a thermoplastic resin or a hot-melt adhesive with a sprayer and drying it. Also, instead of the hot-melt adhesive, a pressure-sensitive adhesive may be used to coat the electric insulator layer. This method has an advantage that the step of fixing the spherical element in the recess of the support can be performed at ordinary temperatures.

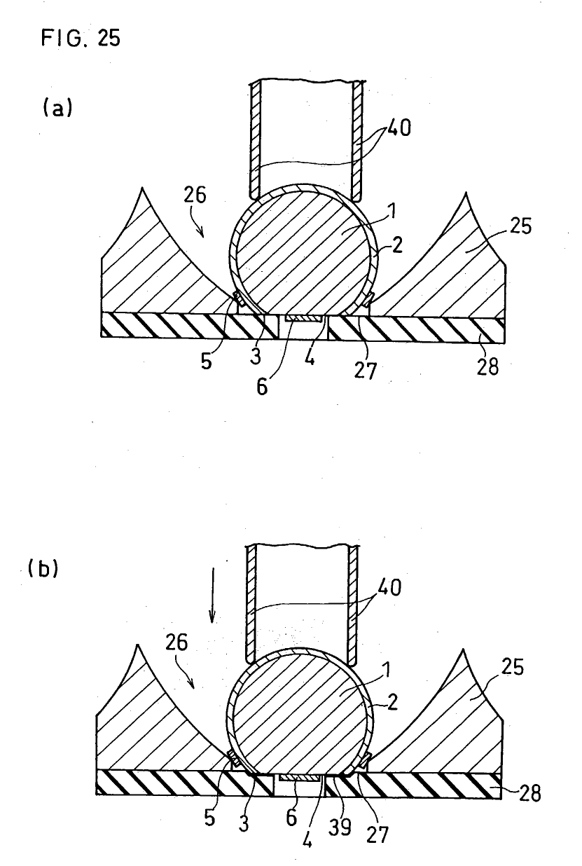

FIG. 25 schematically illustrates the step of melt-welding the spherical element to the predetermined position in the recess of the support using the electric insulator layer made of a thermoplastic resin. The spherical element as illustrated in FIG. 13 is sucked by a heated depressurized metal tube 40 in such a manner that the opening 3 of the second semiconductor layer faces downward. This metal tube 40 is moved to the center of the recess of the support having the same structure as that of FIG. 19 such that the opening 3 of the second semiconductor layer 2 and the exposed part 4 of the first semiconductor 1 of the spherical element are in contact with the electric insulator layer 28 at the circumferential part 27 of the connection hole. This is illustrated in FIG. 25(a).

Subsequently, the metal tube 40 is pushed down approximately 0.1 mm to press the spherical element. Since the spherical element has been heated to a temperature slightly higher than the melting temperature of the electric insulator layer because of heat transfer from the heated metal tube 40, the above-mentioned contact part of the electric insulator layer 28 is melted and melt-welded to the bottom of the spherical element. This is illustrated in FIG. 25(b), in which the melt-welded part of the electric insulator layer 28 is designated by 39. Thereafter, the spherical element is gently released from the metal tube 40 by stopping reducing the pressure of the metal tube 40 and is allowed to cool, whereby the melt-welding is completed.

In the case of using the electric insulator layer coated with a thermoplastic resin or a hot-melt adhesive, the method according to FIG. 25 may also be applied to melt-weld the spherical element. In the case of using the electric insulator layer coated with a pressure-sensitive adhesive, the spherical element can be bonded by the method according to FIG. 25 without heating the metal tube.

It is preferable that the electric insulator layer or the resin material for coating the surface of the electric insulator layer be weather-proof, easily melt-weldable and free from deformation at an operating temperature of approximately 100° C. For example, polycarbonate, acrylic resin, acetal resin, polyamide, polyimide, polyaryl sulfone, polyphenylene sulfide, chlorinated polyeter, or the like may be used. When such a resin is coated to the base material of the electric insulator layer, polyamide, acetal resin or acrylic resin having relatively low thermal deformation temperature may be used among them. In this case, a resin having higher thermal deformation temperature than the coating resin may be used as the base material. The electric insulator layer made of such material can be bonded to the spherical element by thermal welding or ultrasonic welding normally at 150 to 350° C.

It is preferable that the hot-melt adhesive for coating the electric insulator layer be free from softening in an operating temperature range, have lower thermal deformation temperature than the resin material of the base material, and have good adhesion to metal. For example, an adhesive based on an ethylene-vinyl acetate copolymer, polyamide, polyester, or the like may be used. For example, when polyimide is used as the base material, a polyamide based adhesive having lower thermal deformation temperature than the polyimide may be used to bond the spherical element under pressure at 150 to 250° C.

It is also preferable that the pressure-sensitive adhesive satisfy the same requirements as the hot-melt adhesive. For example, natural rubber, synthetic rubber, an acrylic pressure-sensitive adhesive, a silicone pressure-sensitive adhesive, or the like may be used. Further, it is preferable to select a pressure-sensitive adhesive having good adhesion to the base material of the electric insulator layer and to use a silicone pressure-sensitive adhesive when polyimide is used as the base material.

As described above, the spherical element can be disposed in the recess of the support such that the opening of the second semiconductor layer and the peripheral part of the exposed part of the first semiconductor are in contact with the electric insulator layer at the circumferential part of the connection hole.

6. Step (6)

In step (6), the second electrode of the spherical element disposed at the predetermined position in the recess of the support is electrically connected to the second conductor layer of the inner surface of the recess of the support. As this method, the steps (5) and (6) can be performed simultaneously, for example, by designing such that the second electrode of the spherical element comes in contact with the edge or its vicinity of the opening of the second conductor layer as illustrated in FIG. 23.

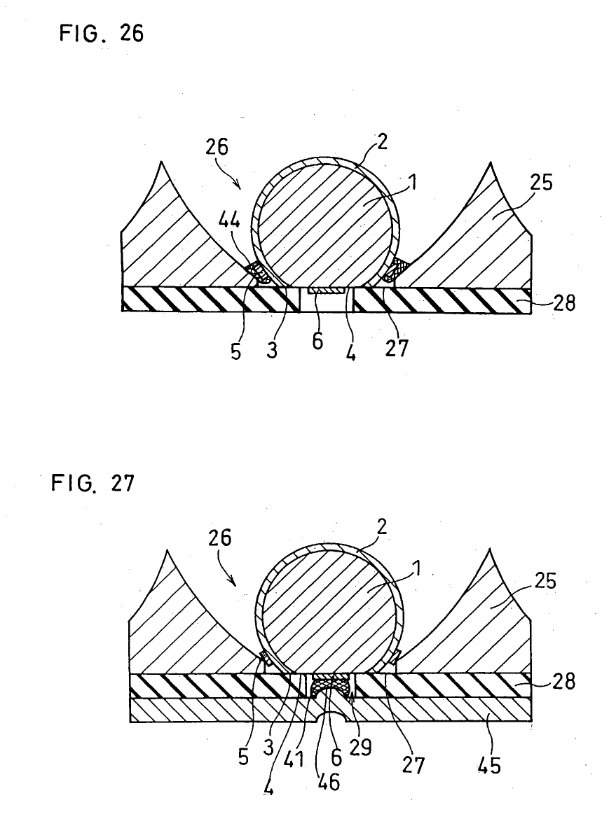

Further, in order to reduce the electrical resistance of the connected part between the second electrode and the second conductor layer and enhance the reliability, it is effective to connect them with solder, conductive material or the like. For example, in the step (5), the spherical element with solder attached to the second electrode is disposed in the recess of the support in such a state as described in FIG. 23. In this step (6), the spherical element is pressed from above, for example, by a hot plate, whereby the spherical element is heated to melt the solder on the second electrode. In this way, the second conductor layer 25 and the second electrode 5 are connected with solder 44 as illustrated in FIG. 26, so that they are electrically connected in a reliable manner while the spherical element is fixed to the predetermined position in the recess of the support more firmly. Although general-purpose solder may be used, it is particularly preferable to use a solder having low melting point in consideration of the heat resistance of the electric insulator layer.

In the case of using conductive material instead of solder to connect the second electrode to the second conductor layer, a conductive-material-containing paste is applied to the second electrode in advance. The spherical element is disposed in the recess of the support before the coating of the conductive-material-containing paste is cured. Then, the coating is cured either at ordinary temperatures or by heating to not higher than approximately 200° C. In this way, in the same manner as the soldering of FIG. 26, the second conductor layer and the second electrode can be connected mechanically and electrically. As the conductive-material-containing paste, a paste prepared by dispersing a fine power of silver or the like as the conductive material in a thermosetting resin such as epoxy resin may be used, for example.

The mechanical and electrical connection between the second conductor layer and the second electrode may be achieved by another method. For example, particles of spherical solder are placed in the gap between the second conductor layer and the second electrode of the spherical element disposed on the support as illustrated in FIG. 23. The spherical element is pressed by a hot plate from above to heat the spherical element and melt the spherical solder for soldering.

As described above, the second electrode of the spherical element can be electrically connected to the second conductor layer of the support. Further, by connecting them with solder, conductive material or the like, the spherical element can be firmly fixed to the predetermined position of the recess of the support.

7. Step (7)

In step (7), the first electrode of the spherical element disposed at the predetermined position of the recess of the support is electrically connected to the first conductor layer through the connection hole. This method will be described below. First, in the step (5), the spherical element with solder attached to the first electrode is disposed at the predetermined position in the recess of the support in such a state as described in FIG. 23. In this step (7), this support is placed on the first conductor layer, made of aluminum foil, placed on a heated mount, and the spherical element is pressed by a presser bar from above. This causes heat transfer from the mount to the bottom of the spherical element, thereby to melt the solder attached to the first electrode, so that the first electrode is soldered to the first conductor layer.

FIG. 27 illustrates the first electrode that is soldered to the first conductor layer in the above manner. A first conductor layer 45 has a projected part 53 that is formed at a position opposite to the connection hole 29, and the projected part 53 is connected to the first electrode 6 with solder 41. This ensures easy and reliable electrical connection between the first conductor layer and the first electrode, and further allows the spherical element to be fixed to the predetermined position in the recess of the support more firmly. Although general-purpose solder may be used, it is particularly preferable to use a solder having low melting point in consideration of the heat resistance of the electric insulator layer.

In the case of using conductive material instead of solder to connect the first conductor layer and the first electrode, a conductive-material-containing paste is applied to the first electrode in advance. The spherical element is disposed in the recess of the support before the applied coating is cured, and the conductive-material-containing paste is cured by heating the support while pressing it in the same manner as the above-described soldering. In this way, the projected part of the first conductor layer and the first electrode can be mechanically and electrically connected in a easy and reliable manner. As the conductive-material-containing paste, a paste prepared by dispersing a fine power of silver or the like as the conductive material in a thermosetting resin such as epoxy resin may be used, for example.

Using spherical solder, the first conductor layer and the first electrode are connected in the following manner. First, the first conductor layer is placed on a heated mount, and the support is aligned with and placed on the first conductor layer such that the projected part of the first conductor layer is inserted into the connection hole of the recess of the support. Subsequently, after spherical solder is inserted into the connection hole, the spherical element is disposed at the predetermined position in the recess of the support and is pressed by a presser bar from above. In this way, the spherical solder is melted to solder the first electrode to the first conductor layer.

Without using solder or conductive material, bringing the projected part of the first conductor layer in direct contact with the first electrode also enables electrical connection between the first conductor layer and the first electrode. In this case, in order to fix the spherical element to the predetermined position, it is preferable to join the electric insulator layer and the first conductor layer by melt-welding, bonding with an adhesive or the like.

As described above, the first conductor layer disposed on the backside of the support can be electrically connected to the first electrode of the spherical element though the connection hole. Further, connecting them with solder, conductive material or the like can produce the effect of firmly fixing the spherical element to the predetermined position in the recess of the support.

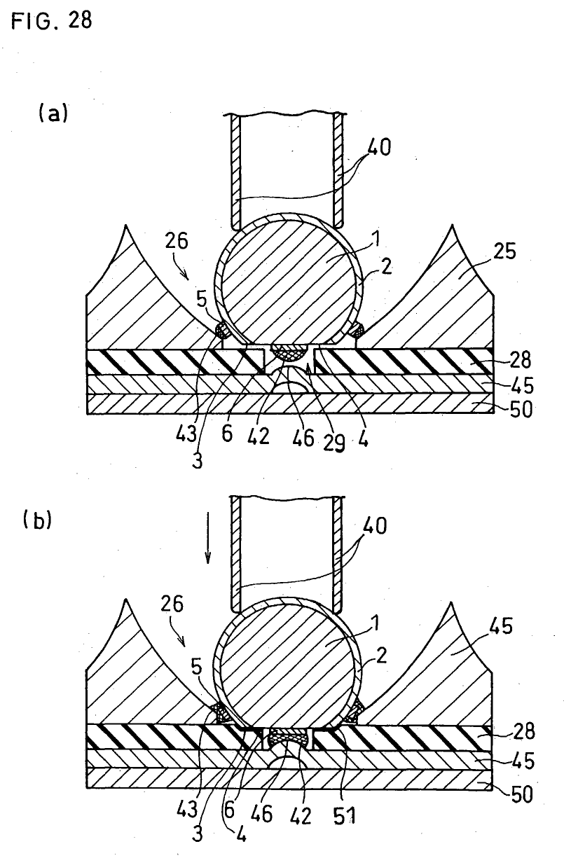

In the production method of a photovoltaic device of the present invention, the step (7) and the step (6) may be performed in a random order. Also, the step (7) and the step (6) may be performed simultaneously with other steps. As one example of simultaneously performing a plurality of steps, the following will specifically describe a method of simultaneously performing the steps (5), (6) and (7), referring to FIG. 28. In this case, however, the step (5) comprises bonding with an adhesive or melt-welding the opening of the second semiconductor layer and the peripheral part of the exposed part of the first semiconductor to the electric insulator layer at the circumferential part of the connection hole, the step (6) comprises electrically connecting the second electrode to the second conductor layer with solder or conductive material, and the step (7) comprises electrically connecting the first electrode to the first conductor layer through the connection hole with solder or conductive material.

First, the first conductor layer 45 made of aluminum foil is placed on an iron mount 50. Then, the support of FIG. 19, which comprises the electric insulator layer 28 made of a thermoplastic resin or coated with a thermoplastic resin or a hot-melt adhesive at the circumferential parts of the connection holes, is placed on the first conductor layer 45. Therein, the support is placed such that the projected part 46 of the first conductor layer 45 is aligned with and fitted in the connection hole 29 of the recess 26 of the support. Subsequently, the spherical element as illustrated in FIG. 13, with solders 42 and 43 attached to the first electrode 6 and the second electrode 5, respectively, is prepared. The spherical element is sucked by the heated metal tube 40 of FIG. 26, and is moved to a position at which the solder 42 attached to the first electrode 6 is fitted into the connection hole 29 of the support, as illustrated in FIG. 28(a).

Thereafter, the metal tube 40 is gently pushed down approximately 0.1 mm to press the spherical element into the recess and then held stationary. Since the spherical element has been heated by heat transfer from the metal tube 40, the solders 42 and 43 attached to the first electrode 6 and the second electrode 5 are melted, so that the first electrode 6 and the projected part 46 of the first conductor layer 45 are soldered simultaneously with the second electrode 5 and the second conductor layer 25 of the recess of the support. Also simultaneously with this, the peripheral part of the exposed part 4 of the first semiconductor 1 and the opening 3 and its vicinity of the second semiconductor layer 2 are melt-welded to the electric insulator layer 28 at the circumferential part of the connection hole 29. This is illustrated in FIG. 28(b), in which the melt-welded part of the electric insulator layer 28 is designated by 51. Subsequently, the spherical element is gently released from the metal tube 40 by stopping reducing the pressure of the metal tube 40 and is allowed to cool. By this procedure, the above-described three steps are performed simultaneously.

In the above procedure, the three steps may also be performed simultaneously as follows. First, instead of solder, a conductive-material-containing paste is applied to the first and second electrodes in advance. The spherical element is moved to the predetermined position in the recess of the support before the applied conductive-material-containing paste is cured, as illustrated in FIG. 28(a), and the applied conductive-material-containing paste is cured while the spherical element is pressed into the recess as illustrated in FIG. 28(b).

The soldering methods in the steps (6) and (7) have an advantage of being able to connect the electrode and the conductor layer in a relatively short period of time. In the case of using spherical solder, in particular, there is also another advantage. By properly setting the conditions such as the dimensions and number of spherical solder particles, the solder can be placed, easily and accurately, in the minute gap between the second electrode on the curved surface of the small spherical element and the curved surface of the recess of the support and the small gap between the first electrode and the first conductor layer.

The following embodiment is one of the most preferable embodiments of the present invention, and while making use of the above-described soldering advantages, this embodiment improves the productivity and quality of the photovoltaic device by performing the step (7) before the step (6) to solder the electrodes of the spherical element to the conductor layers. First, in the step (7), by soldering the first electrode of the spherical element to the first conductor layer with solder (first solder), electrical connection between the first semiconductor of the spherical element and the first conductor layer and fixing of the spherical element to the predetermined position in the recess of the support are ensured while an integral assembly of the spherical element, the support and the first conductor layer is formed. Thereafter, in the step (6), using solder (second solder) having a liquidus temperature lower than the solidus temperature of the first solder, the second electrode is soldered to the second conductor layer at a temperature lower than the solidus temperature of the first solder and not lower than the liquidus temperature of the second solder.

As the first solder, one having a solidus temperature higher than the liquidus temperature of the second solder is used. The liquidus temperature of the first solder is preferably 200 to 300° C., and the liquidus temperature of the second spherical solder is preferably 100 to 200° C. Incidentally, with regard to the melting temperature of solder, there are liquidus temperature and solidus temperature. Solder is in liquid state at temperatures higher than the liquidus temperature and in solid state at temperatures lower than the solidus temperature. At intermediate temperatures between the liquidus temperature and the solidus temperature, solder is in half molten state where solid and liquid coexist. The liquidus temperature is equal to or higher than the solidus temperature, and the difference between them is within 30° C. for many kinds of solders.

In soldering the second electrode to the second conductor layer in the step (6), the use of the above-described first and second solders allows only the second spherical solder to melt without re-melting or half-melting the first solder used in the step (7), to solder the second electrode to the second conductor layer. Therefore, since the integral assembly of the spherical element, the support and the first conductor layer has already been formed in the previous step (7), handling and soldering operation can be performed correctly and readily in the step (6). That is, in the step (6), the spherical element has been fixed to the predetermined position of the support with high accuracy, with the result that an even gap is formed between the second electrode on the outer surface of the spherical element and the second conductor layer of the inner surface of the recess of the support. Therefore, the second solder can be placed in the gap in a predetermined positional relation with high accuracy. This facilitates reliable soldering of the second electrode to the second conductor layer in a correct positional relationship in the step (6), further ensuring the electrical connection between the electrodes and the conductor layers, fixing of the spherical element to the predetermined position and joining of the spherical element, the support and the first conductor layer. This makes a great contribution to stabilization of the step that will be performed later to assemble a photovoltaic module as well as an improvement in reliability of the resultant photovoltaic module.

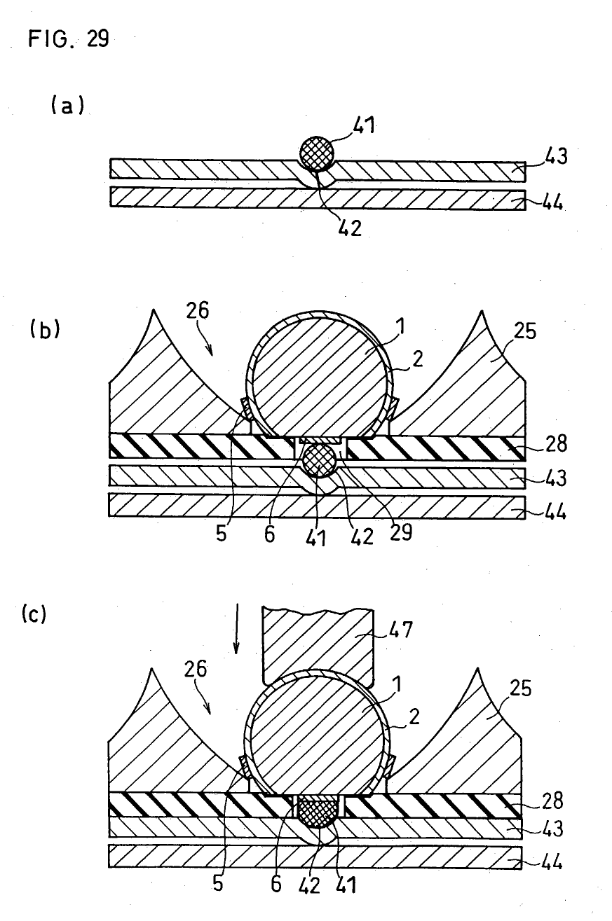

The step (7) of this embodiment comprises a step of placing the first solder between the first electrode and a part of the first conductor layer to be soldered to the first electrode and a step of melting the first spherical solder to solder the first electrode to the first conductor layer. FIG. 29 illustrates these steps with the use of spherical solder as the first solder. As illustrated in FIG. 29(a), a first conductor layer 43, which comprises aluminum foil, silver foil or silver plated metallic foil with a plurality of minute concaves 42 formed in a pattern corresponding to the connection holes of the support, is placed on an iron mount 44, and one first spherical solder particle 41 is disposed in each of the concaves 42 one by one. Subsequently, the support in which the spherical element is melt-welded to the predetermined position of the recess 26 by the method as illustrated in FIG. 25 is prepared. As illustrated in FIG. 29 (b), the support is aligned with and placed on the first conductor layer 43 such that the first spherical solder particle 41 is fitted into each of the connection holes 29 of the support. Thereafter, by pressing the top of the spherical element melt-welded to the recess 26 of the support by a pressure bar 47 while heating the mount 44, the first spherical solder particle 41 is melted by the heat transferred from the mount 44 to solder the first electrode 6 to the first conductor layer 43 as illustrated in FIG. 29(c).

The step (7) of this embodiment may be performed by other methods. For example, the support where the spherical element is fixed to the predetermined position in each of the recesses is turned upside down while being pressed from above by a flat plate, and the first spherical solder is charged into each of the connection holes. Then, the first conductor layer is placed on the support, and is pressed by a hot plate to melt the first spherical solder for soldering. As illustrated in FIG. 27, it is also possible to take a method of soldering the first electrode to the first conductor layer with the first solder that is attached to the first electrode in advance.

In this embodiment, the steps (5) and (7) may be performed simultaneously. A preferable method thereof is as follows. As a preparation, the first conductor layer is disposed on the backside of the support, and the first solder is placed between the first electrode of the spherical element and a part of the first conductor layer to be soldered to the first electrode. Thereafter, the spherical element is pressed into the recess of the support while the first solder and the electric insulator layer of the support are heated. By this method, the opening of the second semiconductor layer and the peripheral part of the exposed part of the first semiconductor can be melt-welded to the electric insulator layer at the circumferential part of the connection hole, simultaneously with the soldering of the first electrode to the first conductor layer with the first spherical solder.

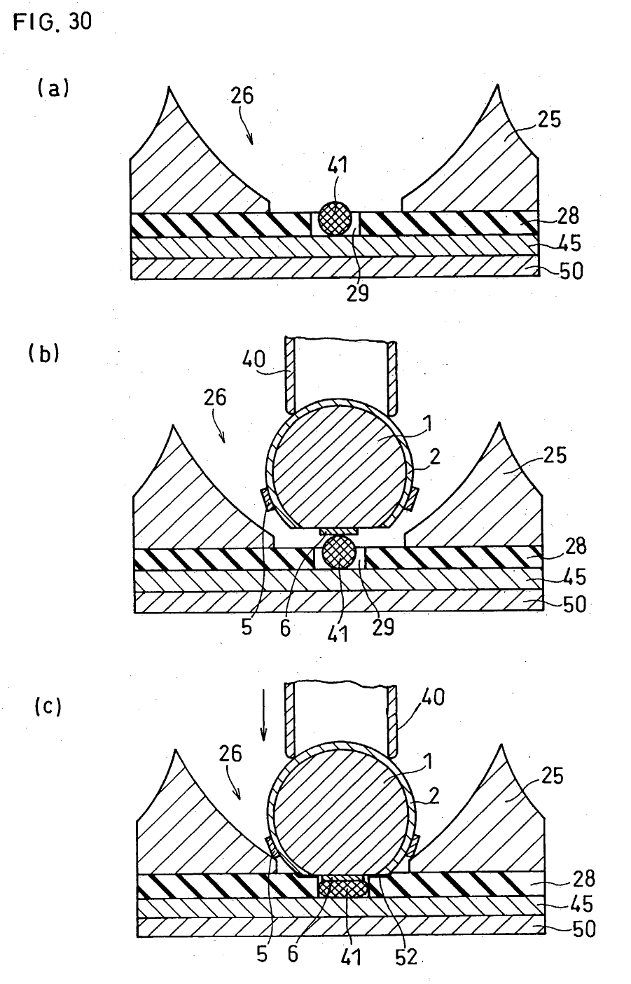

In this case, the first solder is placed to the predetermined position between the first conductor layer and the first electrode by a method of melting and attaching the first solder to the first electrode or by a method of using spherical solder. Of these methods, the method of using spherical solder as the first solder is illustrated in FIG. 30. The first conductor layer 45 is placed on the iron mount 50, and the support as illustrated in FIG. 19 is placed thereon. Then, one particle of the first spherical solder 41 is inserted in the space formed by the first conductor layer 45 and the connection hole 29 of the recess 26 of the support in such a manner that the top of the first spherical solder particle 41 protrudes slightly from the connection hole 29. This is illustrated in FIG. 30(a).

Subsequently, the spherical element as illustrated in FIG. 13 is sucked onto the opening edge of the depressurized metal tube 40 in such a manner that the first electrode 6 faces downward. This metal tube 40 is moved to the center of the recess of the support such that the first electrode 6 formed on the exposed part of the first semiconductor 1 of the spherical element is in contact with the first spherical solder particle 41 inserted into the connection hole 29. This is illustrated in FIG. 30(b).

Thereafter, the metal tube 40 is pushed down to press the spherical element while the mount 50 is heated. Then, the heat transferred from the mount 50 melts the first spherical solder particle 41, and at the same time, softens or melts the electric insulator layer 28 at the circumferential part of the connection hole 29. Accordingly, the opening of the second semiconductor layer 2 and the peripheral part of the exposed part of the first semiconductor are melt-welded to the electric insulator layer 28 at the circumferential part of the connection hole 29, and simultaneously with this, the first electrode 6 is soldered to the first conductor layer 45. This is illustrated in FIG. 30(c), in which a heavy line 52 designates the melt-welded part. It is noted that a minute gap, into which the second spherical solder will be placed in the next step, is formed between the ring-like second electrode 5 on the outer surface of the second semiconductor layer 2 and the inner surface of the second conductor layer 25.

The step of FIG. 30 enables reliable electrical connection between the first semiconductor of the spherical element and the first conductor layer while firmly fixing the spherical element to the predetermined position in the recess of the support. Further, since the spherical element, the support and the first conductor layer are firmly joined together, these members can be handled as one integral assembly in the subsequent steps.

In this embodiment, the step (6) performed after the step (7) comprises a step of placing the second solder having a liquidus temperature lower than the solidus temperature of the first solder between the second conductor layer of the inner surface of the recess of the support and the second electrode of the spherical element soldered to the first conductor layer by the step (7) and a step of heating the second solder at a temperature lower than the solidus temperature of the first solder and not lower than the liquidus temperature of the second solder to solder the second electrode to the second conductor layer.

A specific example of the step (6) of this embodiment will be described. First, the integral assembly of the support, the spherical element and the first conductor layer formed by the step (7) is prepared. Using a dispenser, solder paste containing the second solder is injected between the ring-like second electrode formed on the outer surface of the spherical element of this assembly and the inner surface of the recess of the support. Subsequently, this assembly is heated in a constant temperature bath adjusted to a temperature not lower than the liquidus temperature of the second solder and not higher than the solidus temperature of the first solder to melt the second solder in the solder paste without re-melting the first solder, so that the second electrode is soldered to the inner surface of the second conductor layer. The solder paste used therein is a mixture of a powder of the second solder and flux. An example of the solder paste is one prepared by mixing a powder of the second solder having a particle diameter of 200 to 300 μm with an organic flux composed mainly of rosin so as to have a viscosity of 10 to 20 Pa·s.

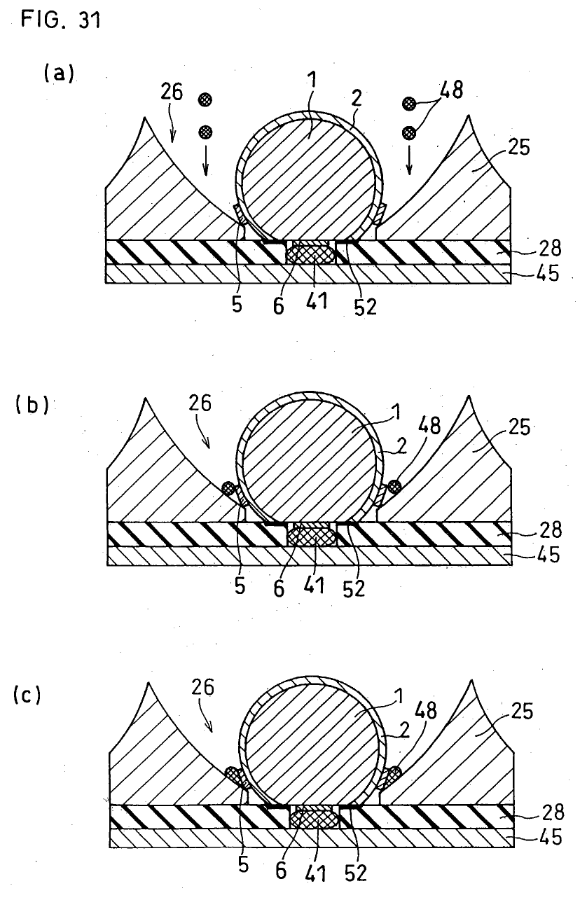

Next, the use of spherical solder as the second solder in the step (6) of this embodiment will be described, referring to FIG. 31. As illustrated in FIG. 31(a), a plurality of (e.g. 10) second spherical solder particles 48 are dropped between the outer surface of the spherical element of the assembly as illustrated in FIG. 30(c) and the inner surface of the recess of the support. Subsequently, this assembly is vibrated lightly to fill the second spherical solder particles 48 into the gap between the ring-like second electrode 5 on the lower outer surface of the spherical element and the inner surface of the second conductor layer 25 or to insert the second spherical solder particles 48 in the gap such that they are slightly spaced. This is illustrated in FIG. 31(b). In this case, the second spherical solder particle preferably has such a diameter that it fits into the gap between the second electrode 5 and the inner surface of the second conductor layer 25.

Thereafter, this assembly with the second spherical solder particles 48 inserted therein is heated in a constant temperature bath adjusted to a temperature not lower than the liquidus temperature of the second spherical solder particles 48 and not higher than the solidus temperature of the first spherical solder particle to melt the second spherical solder particles 48 without re-melting the first spherical solder particle, so that the second electrode 5 is soldered to the inner surface of the second conductor layer 25. This is illustrated in FIG. 31(c). In this way, the second electrode of the spherical element can be electrically connected to the second conductor layer of the support with the second solder, while the spherical element can be fixed to the predetermined position in the recess of the support more firmly.

In this case, it is preferable to insert a plurality of spherical solder particles into the gap between the second electrode and the second conductor layer. The use of two or more of spherical solder particles enables firm soldering and enhances the reliability of soldering.

In this embodiment, when the spherical element has a diameter of 0.5 to 2.0 mm, the first solder is preferably one or more spherical solder particles, of which diameter is not greater than the diameter of the connection hole, not less than the depth of the connection hole and 0.1 to 0.5 mm. In this case, when inserted into the connection hole, the unmelted first spherical solder comes in direct contact with both of the first electrode and the first conductor layer and is melted in this state. Thus, more reliable soldering becomes possible. Further, the second solder is preferably a plurality of spherical solder particles, of which diameter is 0.03 to 0.1 mm. In this case, a plurality of un-melted second spherical solder particles can be fitted into the gap between the second electrode and the inner surface of the second conductor layer, and by melting them, reliable soldering becomes possible.

With respect to the shape of the spherical solder particle used as the first or second solder, it is preferably a complete sphere, but it may be substantially spherical. Also, instead of the spherical solder, palletized solder in the form of a disc, rectangular piece or the like, may be effectively used.

In order to meet the requirements in terms of environmental protection, the first and second solders are preferably lead-free. The first solder is preferably a lead-free solder containing not less than 90% by weight of tin. Specifically, preferable examples include an Sn-Ag solder containing 96.5% by weight of Sn, 0.5 to 3.5% by weight of Ag and optionally 1% by weight of Cu, an Sn-Sb solder containing 90 to 99% by weight of Sn and 1 to 10% by weight of Sb, and an Sn-Ge solder containing 99% by weight of Sn and 1% by weight of Ge. The liquidus temperatures of these solders are in the above-mentioned preferable range of 200 to 300° C.

The second solder preferably contains 40 to 60% by weight of tin and a total of 60 to 40% by weight of indium and bismuth. Preferable examples of the second solder include an Sn-In solder containing 48 to 52% by weight of Sn and 52 to 48% by weight of In and an Sn-Bi solder containing 42% by weight of Sn and 58% by weight of Bi. The liquidus temperatures of these solders are in the above-mentioned preferable range of 100 to 200° C.

In the steps (6) and (7) of the present invention, the surfaces of the first and second electrodes have good affinity for the molten solder, so the solder can be attached to them relatively easily. On the other hand, the surfaces of the first and second conductor layers, made of aluminum or silver, often have poor affinity for the molten solder, so it is difficult to reliably solder the electrode to the conductor layer. Accordingly, in the step (7), it is preferable to preliminarily attach solder thinly to at least the part of the first conductor layer to be soldered to the first electrode prior to the step of soldering the first electrode to the first conductor layer. The solder applied preliminarily is hereinafter referred to as preliminary solder. In the step (6), it is preferable to apply preliminary solder to at least the part of the second conductor layer to be soldered to the second electrode prior to the step of soldering the second electrode to the second conductor layer. This ensures more reliable soldering of the electrode and the conductor layer.

Preliminary solder may be applied by a method of applying solder paste thinly onto the conductor layer, a method of attaching molten solder with flux thinly, a method of solder-plating, or the like. Preferably, it is applied by a method of applying solder paste onto the predetermined part of the conductor layer by an ink-jet printer or a dispenser. These methods have an advantage of being capable of forming a preliminary solder layer on the minute parts of the first and second conductor layers with high accuracy. Application of the solder paste by these methods may be performed according to the application methods of the conductive ink for forming the first or second electrode, which were explained in Step (2) or Step (3).

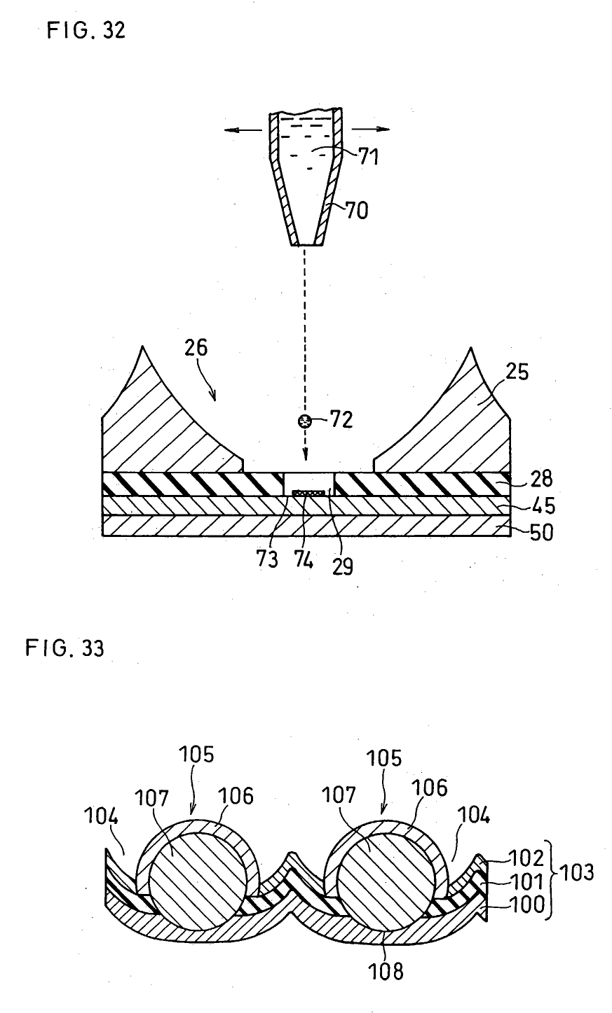

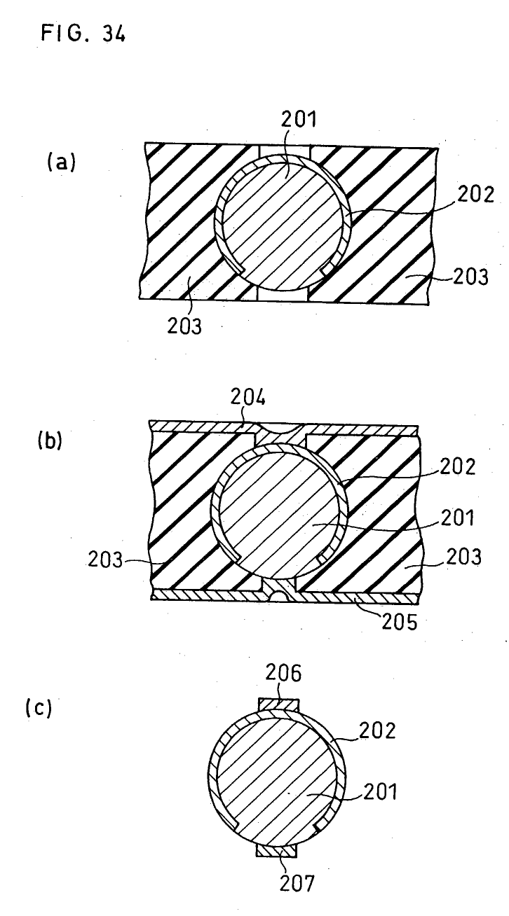

As an example of the method of preliminary solder application, the following will describe a method of applying solder paste onto the first conductor layer by the ink-jet printer. Prior to the step of disposing the spherical solder as illustrated in FIG. 30(a), solder paste is applied onto the first conductor layer by an ink-jet printer as illustrated in FIG. 32. From an ink-jet head 70, a fine droplet 72 of solder paste 71 is jetted in the direction of the arrow such that the droplet 72 adheres almost vertically to an exposed part 73 of the first conductor layer 45 at the bottom of the connection hole 29 of the electric insulator layer 28 which is the bottom of the support.

If the droplet 72 of the solder paste 71 is jetted, for example, in an amount of approximately 40 picoliter from the ink-jet head 70, a solder paste layer having a diameter of approximately 100 μm and a thickness of approximately 5 μm is formed. While the ink-jet head 70 is continuously moved slightly in the directions of X-Y axes, the droplet 72 of the solder paste 71 is jetted to the exposed part 73 to form a circular solder paste layer 74 having a diameter of approximately 300 μm and a thickness of approximately 5 μm within the exposed part 73. As the solder paste, one prepared by mixing a fine powder of solder with e.g. an organic flux composed mainly of rosin is used. In view of the applicability, it is preferable to use a solder paste comprising a fine solder powder of 0.1 to 10 μm in diameter and having a viscosity of 1 to 10 Pa·s.

If the solder paste is applied relatively thickly onto the conductor layer in the same manner as the method of applying preliminary solder, the applied layer may also be used as the solder for soldering the electrode to the conductor layer in the steps (6) and (7).

The photovoltaic device in accordance with the present invention is a high-quality and high-performance photovoltaic device that is produced according the production methods of the present invention. The essential feature of the photovoltaic device in accordance with the present invention is that the spherical element on which the first and second electrodes are formed is disposed at the predetermined position in each recess of the support and that the first electrode and the second electrode are electrically connected to the first conductor layer and the second conductor layer, respectively. It is preferable that the electrical connection between them is achieved with solder or conductive material. This makes it possible to obtain excellent electrical connection between the first semiconductor and the first conductor layer and between the second semiconductor layer and the second conductor layer, and further allows the spherical element to be fixed to the predetermined position in the recess of the support. Further, the surface of the electric insulator layer at the circumferential part of the connection hole has a shape corresponding to the shape of the peripheral part of the exposed part of the first conductivity-type semiconductor and the opening of the second conductivity-type semiconductor layer. This makes it possible to dispose the spherical element at the predetermined position in the recess of the support in a correct and stable state.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

1. A method of producing a photovoltaic device comprising the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) disposing the photovoltaic element in the recess of the support such that the opening of the second conductivity-type semiconductor layer and a peripheral part of the exposed part of the first conductivity-type semiconductor are in contact with the electric insulator layer around the connection hole; (6) electrically connecting the second electrode to the second conductor layer; and (7) electrically connecting the first electrode to a first conductor layer disposed on the backside of the support through the connection hole.

2. The method of producing a photovoltaic device in accordance with claim 1, wherein the first conductivity-type semiconductor and the second conductivity-type semiconductor layer are composed mainly of silicon.

3. The method of producing a photovoltaic device in accordance with claim 1, wherein the step (2) comprises applying a conductive ink onto the exposed part of the first conductivity-type semiconductor and subjecting it to a heat treatment.

4. The method of producing a photovoltaic device in accordance with claim 3, wherein the conductive ink comprises glass frit and at least one selected from the group consisting of silver, aluminum, tin, nickel, copper, phosphorus and phosphorus compounds, and the temperature range of the heat treatment is 500 to 750° C.

5. The method of producing a photovoltaic device in accordance with claim 1, wherein the step (3) comprises applying a conductive ink onto a part of the surface of the second conductivity-type semiconductor layer and subjecting it to a heat treatment.

6. The method of producing a photovoltaic device in accordance with claim 5, wherein the conductive ink comprises glass frit and at least one selected from the group consisting of silver, aluminum, tin, nickel, copper, phosphorus and phosphorus compounds, and the temperature range of the heat treatment is 500 to 750° C.

7. The method of producing a photovoltaic device in accordance with claim 1, wherein the second electrode comprises a portion electrically connected to an external terminal and a portion collecting electric current from the second conductivity-type semiconductor layer, and these portions are in contact with each other.

8. The method of producing a photovoltaic device in accordance with claim 1, wherein the step (5) comprises bonding with an adhesive or melt-welding the opening of the second conductivity-type semiconductor layer and the peripheral part of the exposed part of the first conductivity-type semiconductor to the electric insulator layer around the connection hole.

9. The method of producing a photovoltaic device in accordance with claim 8, wherein the surface of the electric insulator layer is made of a thermoplastic resin at least around the connection hole.

10. The method of producing a photovoltaic device in accordance with claim 8, wherein the surface of the electric insulator layer is coated with a hot-melt adhesive or a pressure-sensitive adhesive at least around the connection hole.

11. The method of producing a photovoltaic device in accordance with claim 1, wherein at least one of the steps (6) and (7) comprises connecting the electrode to the conductor layer with solder or conductive material.

12. The method of producing a photovoltaic device in accordance with claim 11, wherein the solder is spherical solder or palletized solder.

13. The method of producing a photovoltaic device in accordance with claim 11, further comprising preliminarily applying solder onto the surface of at least a part of the conductor layer to be soldered to the electrode prior to connecting the electrode to the conductor layer with solder.

14. The method of producing a photovoltaic device in accordance with claim 13, wherein the preliminarily applying solder comprises applying solder paste onto the surface of the conductor layer.

15. A method of producing a photovoltaic element comprising the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) bonding with an adhesive or melt-welding the opening of the second conductivity-type semiconductor layer and the peripheral part of the exposed part of the first conductivity-type semiconductor to the electric insulator layer around the connection hole to fix the photovoltaic element into the recess of the support; (6) connecting the second electrode to the second conductor layer with solder or conductive material; and (7) connecting the first electrode to a first conductor layer disposed on the backside of the support through the connection hole with solder or conductive material,
wherein the steps (5), (6) and (7) are performed simultaneously by pressing, while heating, the photovoltaic element, with solder or a conductive-material-containing paste placed between the second electrode and a part of the second conductor layer to be connected to the second electrode and between the first electrode and a part of the first conductor layer to be connected to the first electrode.

16. A method of producing a photovoltaic element comprising the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) bonding with an adhesive or melt-welding the opening of the second conductivity-type semiconductor layer and the peripheral part of the exposed part of the first conductivity-type semiconductor to the electric insulator layer around the connection hole to fix the photovoltaic element into the recess of the support; (6) electrically connecting the second electrode to the second conductor layer; and (7) connecting the first electrode to a first conductor layer disposed on the backside of the support through the connection hole with solder,
wherein the steps (5) and (7) are performed simultaneously by pressing the photovoltaic element in such a direction as to bring the opening of the second conductivity-type semiconductor layer and the peripheral part of the exposed part of the first conductivity-type semiconductor in contact with the electric insulator layer around the connection hole, with solder placed between the first electrode and a part of the first conductor layer to be soldered to the first electrode, while heating the solder and the electric insulator layer.

17. A method of producing a photovoltaic element comprising the steps of: (1) providing a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed; (2) forming a first electrode on the exposed part of the first conductivity-type semiconductor of the photovoltaic element; (3) forming a second electrode on a part of the surface of the second conductivity-type semiconductor layer of the photovoltaic element; (4) providing a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; (5) disposing the photovoltaic element in the recess of the support such that the opening of the second conductivity-type semiconductor layer and a peripheral part of the exposed part of the first conductivity-type semiconductor are in contact with the electric insulator layer around the connection hole; (6) connecting the second electrode to the second conductor layer with solder; and (7) connecting the first electrode to a first conductor layer disposed on the backside of the support through the connection hole with solder,
wherein the step (7) comprises placing a first solder between the first electrode and a part of the first conductor layer to be soldered to the first electrode and heating the first solder to solder the first electrode to the first conductor layer and is performed before the step (6), and the step (6) comprises placing a second solder having a liquidus temperature lower than the solidus temperature of the first solder between the second conductor layer of the support and the second electrode of the photovoltaic element soldered to the first conductor layer by the step (7) and heating the second solder at a temperature lower than the solidus temperature of the first solder and not lower than the liquidus temperature of the second solder to solder the second electrode to the second conductor layer.

18. The method of producing a photovoltaic device in accordance with claim 17,
wherein the diameter of the photovoltaic element is 0.5 to 2.0 mm,
the first solder is one or more spherical solder particles, of which diameter is not greater than the diameter of the connection hole, not less than the depth of the connection hole and 0.1 to 0.5 mm, and
the second solder is a plurality of spherical solder particles, of which diameter is 0.03 to 0.1 mm.

19. The method of producing a photovoltaic device in accordance with claim 17, wherein the liquidus temperature of the first solder is 200 to 300° C., and the liquidus temperature of the second solder is 100 to 200° C.

20. The method of producing a photovoltaic device in accordance with claim 17, wherein the first solder contains not less than 90% by weight of tin.

21. The method of producing a photovoltaic device in accordance with claim 17, wherein the second solder contains 40 to 60% by weight of tin and a total of 60 to 40% by weight of indium and bismuth.

22. A photovoltaic device comprising: a plurality of substantially spherical photovoltaic elements, each comprising a spherical first conductivity-type semiconductor and a second conductivity-type semiconductor layer covering the surface of the first conductivity-type semiconductor, the second conductivity-type semiconductor layer having an opening through which a part of the first conductivity-type semiconductor is exposed, a first electrode being formed on the exposed part of the first conductivity-type semiconductor, a second electrode being formed on a part of the surface of the second conductivity-type semiconductor layer; a support having a plurality of recesses which are arranged adjacent to one another, each of the recesses having a connection hole in its bottom and receiving each of the photovoltaic elements, the support comprising an electric insulator layer having the connection holes and a second conductor layer which is formed on the electric insulator layer except around the connection holes and which constitutes the inner surface of the recesses; and a first conductor layer disposed on the backside of the support,
wherein the second electrode of the photovoltaic element disposed in the recess is electrically connected to the second conductor layer, and the first electrode is electrically connected to the first conductor layer through the connection hole.

23. The photovoltaic device in accordance with claim 22, wherein at least either the second electrode and the second conductor layer or the first electrode and the first conductor layer are connected to each other with solder or conductive material.

24. The photovoltaic device in accordance with claim 22, wherein the surface of the electric insulator layer around the connection hole has a shape corresponding to the shape of the peripheral part of the exposed part of the first conductivity-type semiconductor and the opening of the second conductivity-type semiconductor layer.
